(19) United States
(12) Patent Application Publication
(10) Pub. No.: US 2010/0112211 A1
(43) Pub. Date: May 6, 2010

(54) ZIRCONIUM, HAFNIUM, TITANIUM, AND SILICON PRECURSORS FOR ALD/CVD

(75) Inventors: Chongying Xu, New Milford, CT (US); Jeffrey F. Roeder, Brookfield, CT (US); Tianniu Chen, Rocky Hill, CT (US); Bryan C. Hendrix, Danbury, CT (US); Brian Benac, Marble Falls, TX (US); Thomas M. Cameron, Newtown, CT (US); David W. Peters, Kingsland, TX (US); Gregory T. Stauf, New Milford, CT (US); Leah Maylott, Enfield, CT (US)

Correspondence Address: INTELLECTUAL PROPERTY / TECHNOLOGY LAW, PO BOX 14329, RESEARCH TRIANGLE PARK, NC, 27709, US

(73) Assignee: ADVANCED TECHNOLOGY MATERIALS, INC., Danbury, CT (US)

(21) Appl. No.: 12/595,383

(22) PCT Filed: Apr. 13, 2008
(86) PCT No.: PCT/US08/60162

§ 371 Date: Oct. 9, 2009

Related U.S. Application Data
(60) Provisional application No. 60/911,296, filed on Apr. 12, 2007.
(60) Provisional application No. 60/977,083, filed on Oct. 2, 2007.
(60) Provisional application No. 60/981,020, filed on Oct. 18, 2007.

(51) Int. Cl. C23C 16/00; C07F 7/00; C09D 1/00

(52) U.S. Cl. 427/248.1; 556/52; 106/287.11; 106/287.19

(57) ABSTRACT

Zirconium, hafnium, titanium and silicon precursors useful for atomic layer deposition (ALD) and chemical vapor deposition (CVD) of corresponding zirconium-containing, hafnium-containing, titanium-containing and silicon-containing films, respectively. The disclosed precursors achieve highly conformal deposited films characterized by minimal carbon incorporation.

### CROSS-REFERENCE TO RELATED APPLICATIONS

The present application claims the benefit of the filing dates of U.S. Provisional Patent Application No. 60/911,296 filed Apr. 12, 2007, U.S. Provisional Patent Application No. 60/977,083 filed Oct. 2, 2007, and U.S. Provisional Patent Application No. 60/981,020 filed Oct. 18, 2007. The disclosures of all of said U.S. Provisional Patent Applications are hereby incorporated herein by reference, in their respective entireties, for all purposes.

### FIELD OF THE INVENTION

The present invention relates to zirconium, hafnium, titanium and silicon precursors useful for atomic layer deposition (ALD) and chemical vapor deposition (CVD) of corresponding zirconium-containing, hafnium-containing, titanium-containing and silicon-containing films, respectively. In one specific aspect, zirconium precursors of the invention are utilized for depositing zirconium oxide and zirconium silicate on substrates.

### DESCRIPTION OF THE RELATED ART

The semiconductor manufacturing industry is broadly engaged in the search for new precursors for use in thin film deposition processes, such as chemical vapor deposition (CVD) and atomic layer deposition (ALD).

In general, precursors are sought that are readily volatilizable and transportable to the deposition location, at temperatures consistent with fabrication of microelectronic device structures and materials limitations. Desirable precursors produce highly conformal films on the substrate with which precursor vapor is contacted, without the occurrence of degradation and decomposition reactions that would adversely impact the product device structure.

The industry has particular need of precursors for deposition of zirconium, hafnium, titanium and silicon.

By way of example, ZrO₂ and ZrSiO₃ thin films are currently of great interest for use as high k dielectric materials. Such films are advantageously deposited by CVD and ALD techniques on structures with high aspect ratios.

Although zirconium-containing thin films have demonstrated potential for high k applications in microelectronic device applications, presently available zirconium precursors have associated deficiencies that have limited their use. For example, one widely used Zr precursor is Zr(NEtMe)₄, tetrakis(ethylmethylamido)zirconium (TEMAZ). At high deposition temperatures, this precursor produces Zr-containing films having poor conformality. At low deposition temperatures, conformality is improved, but the resulting films have a high level of incorporated carbon impurities.

The art continues to seek improvements in precursors for deposition of zirconium, hafnium, titanium and silicon.

### SUMMARY OF THE INVENTION

The present invention relates to zirconium, hafnium, titanium and silicon precursors useful for atomic layer deposition (ALD) and chemical vapor deposition (CVD) of corresponding zirconium-containing, hafnium-containing, titanium-containing and silicon-containing films, respectively.

In various specific embodiments, the invention relates to zirconium precursors useful for depositing zirconium oxide and zirconium silicate on substrates via CVD and ALD techniques.

In one aspect, the invention relates to a deposition process, e.g., selected from among CVD and ALD, comprising contacting a substrate with a vapor of a precursor to deposit a film thereon containing at least one of zirconium, hafnium, titanium and silicon (as the metal or metalloid species M), wherein said precursor comprises a compound selected from the group consisting of compounds of the formulae:

M(NR₂)₄, wherein each R may be the same as or different from the others and each is independently selected from among hydrogen, C₁-C₁₂ alkyl, C₃-C₁₀ cycloalkyl, C₂-C₈ alkenyl (e.g., vinyl, allyl, etc.), C₁-C₁₂ alkylsilyl (including monoalkylsilyl, dialkylsilyl and trialkylsilyl), C₆-C₁₀ aryl, —(CH₂)ₓNR′R″, —(CH₂)ₓOR″′ and —NR′R″, wherein x=1, 2 or 3, and R′, R″ and R″′ may be the same as or different from one another, and each is independently selected from H and C₁-C₁₂ alkyl;

(R¹NC(R³R⁴)ₘNR²)_{(OX-n)/2}MXₙ, wherein R¹, R², R³, R⁴ and X may be the same as or different from one another and each is independently selected from among hydrogen, C₁-C₁₂ alkyl, C₃-C₁₀ cycloalkyl, C₂-C₆ alkenyl (e.g., vinyl, allyl, etc.), C₁-C₁₂ alkylsilyl (including monoalkylsilyl, dialkylsilyl, and trialkylsilyl), C₆-C₁₀ aryl, —(CH₂)ₓNR′R″, —(CH₂)ₓOR″′ and —NR′R″, wherein x=1, 2 or 3, and R′, R″ and R″′ can be the same as or different from one another, and each is independently selected from H and C₁-C₁₂ alkyl, wherein the subscripts 1 through 12 in the sequence of carbon numbers designates the number of carbon atoms in the alkyl substituent; m is an integer having a value of from 1 to 6, and in addition, X can be selected from among C₁-C₁₂ alkoxy, carboxylates; beta-diketonates, beta-diketiminates, and beta-diketoiminates, guanidinates, amidinates and isoureates; and further wherein C(R³R⁴)ₘ can be alkylene; OX is the oxidation state of the metal M; n is an integer having a value of from 0 to OX; m is an integer having a value of from 1 to 6;

M(E)₂(OR³)₂ wherein E is substituted dionato, each R³ is the same as or different from the other, and each is independently selected from among C₁-C₁₂ alkyl, C₃-C₁₀ cycloalkyl, C₂-C₈ alkenyl (e.g., vinyl, allyl, etc.), C₁-C₁₂ alkylsilyl (including monoalkylsilyl, dialkylsilyl and trialkylsilyl), C₆-C₁₀ aryl, —(CH₂)ₓNR′R″, —(CH₂)ₓOR″′ and —NR′R″, wherein x=1, 2 or 3, and R′, R″ and R″′ may be the same as or different from one another, and each is independently selected from H and C₁-C₁₂ alkyl, and preferably from among i-propyl and t-butyl (i-propyl being isopropyl and t-butyl being tertiary butyl);

M(OR³)₄ wherein each R³ is the same as or different from the other, and each is independently selected from among C₁-C₁₂ alkyl, C₃-C₁₀ cycloalkyl, C₂-C₈ alkenyl (e.g., vinyl, allyl, etc.), C₁-C₁₂ alkylsilyl (including monoalkylsilyl, dialkylsilyl and trialkylsilyl), C₆-C₁₀ aryl, —(CH₂)ₓNR′R″, —(CH₂)ₓOR″′ and —NR′R″, wherein x=1, 2 or 3, and R′, R″ and R″′ may be the same as or different from one another, and each is independently selected from H and C₁-C₁₂ alkyl, and preferably from among i-propyl and t-butyl;

M(OPr-i)₄-IPA wherein IPA is isopropyl alcohol and OPr-i is isopropoxy;

(R⁶R⁷N)₂M(R⁸NC(R³R⁴)ₘNR⁹) wherein R³, R⁴, R⁶ and R⁷, R⁸ and R⁹ may be the same as or different from one another and each is independently selected from among hydrogen, C₁-C₁₂ alkyl, C₃-C₁₀ cycloalkyl, C₂-C₈ alkenyl (e.g., vinyl, allyl, etc.), C₁-C₁₂ alkylsilyl (including monoalkylsilyl, dialkylsilyl and trialkylsilyl), C₆-C₁₀ aryl, —(CH₂)ₓNR′R″, —(CH₂)ₓOR″′ and —NR′R″, wherein x=1, 2 or 3, and R′, R″ and R″′ may be the same as or different from one another, and each is independently selected from H and C₁-C₁₂ alkyl; and m is an integer having a value of from 1 to 6;

compounds selected from among (amidinate)_{OX-n}MXₙ, (guanidinate)_{OX-n}MXₙ and (isoureate)_{OX-n}MXₙ, wherein each X can be the same as or different from the others and each is independently selected from among hydrogen, C₁-C₁₂ alkyl, C₃-C₁₀ cycloalkyl, C₂-C₆ alkenyl (e.g., vinyl, allyl, etc.), C₁-C₁₂ alkylsilyl (including monoalkylsilyl, dialkylsilyl, and trialkylsilyl), C₆-C₁₀ aryl, —(CH₂)ₓNR′R″, —(CH₂)ₓOR″′ and NR′R″, wherein x=1, 2 or 3, and R′, R″ and R″′ can be the same as or different from one another, and each is independently selected from H and C₁-C₁₂ alkyl, wherein the subscripts 1 through 12 in the sequence of carbon numbers designates the number of carbon atoms in the alkyl substituent; m is an integer having a value of from 1 to 6, and in addition, X can be selected from among C₁-C₁₂ alkoxy, carboxylates; beta-diketonates, beta-diketiminates, and beta-diketoiminates, guanidinates, amidinates and isoureates; OX is the oxidation state of the metal M; n is an integer having a value of from 0 to OX; m is an integer having a value of from 1 to 6,

wherein M is selected from the group consisting of zirconium, hafnium, titanium and silicon.

Another aspect of the invention relates to a precursor comprising a zirconium, hafnium, titanium or silicon compound, selected from the group consisting of compounds of the formulae:

M(NR₂)₄, wherein each R may be the same as or different from the others and each is independently selected from among hydrogen, C₁-C₁₂ alkyl, C₃-C₁₀ cycloalkyl, C₂-C₈ alkenyl (e.g., vinyl, allyl, etc.), C₁-C₁₂ alkylsilyl (including monoalkylsilyl, dialkylsilyl and trialkylsilyl), C₆-C₁₀ aryl, —(CH₂)ₓNR′R″, —(CH₂)ₓOR″′ and —NR′R′, wherein x=1, 2 or 3, and R′, R″ and R″′ may be the same as or different from one another, and each is independently selected from H and C₁-C₁₂ alkyl;

(R¹NC(R³R⁴)ₘNR²)_{(OX-n)/2}MXₙ, wherein R¹, R², R³, R⁴ and X may be the same as or different from one another and each is independently selected from among hydrogen, C₁-C₁₂ alkyl, C₃-C₁₀ cycloalkyl, C₂-C₆ alkenyl (e.g., vinyl, allyl, etc.), C₁-C₁₂ alkylsilyl (including monoalkylsilyl, dialkylsilyl, and trialkylsilyl), C₆-C₁₀ aryl, —(CH₂)ₓNR′R″, —(CH₂)ₓOR″′ and —NR′R″, wherein x=1, 2 or 3, and R′, R″ and R″′ can be the same as or different from one another, and each is independently selected from H and C₁-C₁₂ alkyl, wherein the subscripts 1 through 12 in the sequence of carbon numbers designates the number of carbon atoms in the alkyl substituent; m is an integer having a value of from 1 to 6, and in addition, X can be selected from among C₁-C₁₂ alkoxy, carboxylates; beta-diketonates, beta-diketiminates, and beta-diketoiminates, guanidinates, amidinates and isoureates; OX is the oxidation state of the metal M; n is an integer having a value of from 0 to OX; m is an integer having a value of from 1 to 6;

M(E)₂(OR³)₂ wherein E is substituted dionato, each R³ is the same as or different from the other, and each is independently selected from among C₁-C₁₂ alkyl, C₃-C₁₀ cycloalkyl, C₂-C₈ alkenyl (e.g., vinyl, allyl, etc.), C₁-C₁₂ alkylsilyl (including monoalkylsilyl, dialkylsilyl and trialkylsilyl), C₆-C₁₀ aryl, —(CH₂)ₓNR′R″, —(CH₂)ₓOR″′ and —NR′R″, wherein x=1, 2 or 3, and R′, R″ and R″′ may be the same as or different from one another, and each is independently selected from H and C₁-C₁₂ alkyl, and preferably from among i-propyl and t-butyl (i-propyl being isopropyl and t-butyl being tertiary butyl);

M(OR³)₄ wherein each R³ is the same as or different from the other, and each is independently selected from among C₁-C₁₂ alkyl, C₃-C₁₀ cycloalkyl, C₂-C₈ alkenyl (e.g., vinyl, allyl, etc.), C₁-C₁₂ alkylsilyl (including monoalkylsilyl, dialkylsilyl and trialkylsilyl), C₆-C₁₀ aryl, —(CH₂)ₓNR′R″, —(CH₂)ₓOR″′ and —NR′R″, wherein x=1, 2 or 3, and R′, R″ and R″′ may be the same as or different from one another, and each is independently selected from H and C₁-C₁₂ alkyl, and preferably from among i-propyl and t-butyl;

M(OPr-i)₄-IPA wherein IPA is isopropyl alcohol and OPr-i is isopropoxy;

(R⁶R⁷N)₂M(R⁸NC(R³R⁴)ₘNR⁹) wherein R³, R⁴, R⁶ and R⁷, R⁸ and R⁹ may be the same as or different from one another and each is independently selected from among hydrogen, C₁-C₁₂ alkyl, C₃-C₁₀ cycloalkyl, C₂-C₈ alkenyl (e.g., vinyl, allyl, etc.), C₁-C₁₂ alkylsilyl (including monoalkylsilyl, dialkylsilyl and trialkylsilyl), C₆-C₁₀ aryl, —(CH₂)ₓNR′R″, —(CH₂)ₓOR″′ and —NR′R″, wherein x=1, 2 or 3, and R′, R″ and R″′ may be the same as or different from one another, and each is independently selected from H and C₁-C₁₂ alkyl; and further wherein both of R⁶ or R⁷ groups of respective amino nitrogen atoms in the (R⁶R⁷N)₂ moiety can together be alkylene, and C(R³R⁴)ₘ in the (R⁸NC(R³R⁴)ₘNR⁹) moiety can be alkylene; and m is an integer having a value of from 1 to 6.

compounds selected from among (amidinate)_{OX-n}MXₙ, (guanidinate)_{OX-n}MXₙ and (isoureate)_{OX-n}MXₙ, wherein each X can be the same as or different from the others and each is independently selected from among hydrogen, C₁-C₁₂ alkyl, C₃-C₁₀ cycloalkyl, C₂-C₆ alkenyl (e.g., vinyl, allyl, etc.), C₁-C₁₂ alkylsilyl (including monoalkylsilyl, dialkylsilyl, and trialkylsilyl), C₆-C₁₀ aryl, —(CH₂)ₓNR′R″, —(CH₂)ₓOR″′ and NR′R″, wherein x=1, 2 or 3, and R′, R″ and R″′ can be the same as or different from one another, and each is independently selected from H and C₁-C₁₂ alkyl, wherein the subscripts 1 through 12 in the sequence of carbon numbers designates the number of carbon atoms in the alkyl substituent; m is an integer having a value of from 1 to 6, and in addition, X can be selected from among C₁-C₁₂ alkoxy, carboxylates; beta-diketonates, beta-diketiminates, and beta-diketoiminates, guanidinates, amidinates and isoureates; OX is the oxidation state of the metal M; n is an integer having a value of from 0 to OX; m is an integer having a value of from 1 to 6,

wherein M is selected from the group consisting of zirconium, hafnium, titanium and silicon.

In another aspect, the invention relates to a zirconium precursor, selected from the group consisting of compounds of the formulae:

Zr(NMe₂)₄;

[R¹N(CR³R⁴)ₘNR²]₂Zr wherein R¹, R², R³, and R⁴ may be the same as or different from one another and each is independently selected from among C₁-C₁₂ alkyl;
Zr(E)₂(OR³)₂ wherein E is a substituted dionato ligand, e.g., a β-diketonate such as 2,2,6,6-tetramethyl-3,5-heptanedionato, sometimes herein denoted “thd,” or other β-diketonate ligand, and wherein each R³ is the same as or different from the other, and each is independently selected from among i-propyl and t-butyl;
Zr(OR³)₄ wherein each R³ is the same as or different from the other, and each is independently selected from among i-propyl and t-butyl;
Zr(OPr-i)₄-IPA wherein IPA is isopropyl alcohol and OPr-i is isopropoxy;
(R⁶R⁷N)₂Zr(R⁸NC(R³R⁴)ₘNR⁹) wherein R³, R⁴, R⁶, R⁷, R⁸ and R⁹ may be the same as or different from one another and each is independently selected from among C₁-C₁₂ alkyl;
(guanidinate)Zr(NR¹⁰R¹¹)₃ wherein guanidinate may be substituted or unsubstituted, R⁸ and R⁹ may be the same as or different from one another and each is independently selected from among C₁-C₁₂ alkyl.

A still further aspect of the invention relates to a method of depositing a zirconium-containing film, on a substrate, comprising conducting CVD or ALD with a zirconium precursor of the invention.

In a further aspect, the invention relates to a precursor of the invention, as packaged in a precursor storage and dispensing package.

A further aspect of the invention relates to a precursor vapor composition comprising vapor of a precursor of the invention.

A still further aspect of the invention relates to a precursor formulation, comprising a precursor of the invention, and a solvent medium.

Another aspect of the invention relates to a liquid delivery process for deposition of a film on a substrate, comprising volatilizing a liquid precursor composition to form a precursor vapor, and contacting such precursor vapor with the substrate to deposit said film thereon, wherein the precursor composition includes a precursor of the invention.

A still further aspect of the invention relates to a aspect of the invention relates to a solid delivery process for deposition of a film on a substrate, comprising volatilizing a solid precursor composition to form a precursor vapor, and contacting the precursor vapor with the substrate to deposit the film thereon, wherein the precursor composition includes a precursor of the invention.

Yet another aspect of the invention relates to a method of making a zirconium, hafnium, titanium or silicon precursor, comprising reacting a zirconium, hafnium, titanium or silicon amide with a carbodiimide to yield the precursor.

A further aspect of the invention relates to a method of making a zirconium, hafnium, titanium or silicon precursor, comprising conducting the reaction

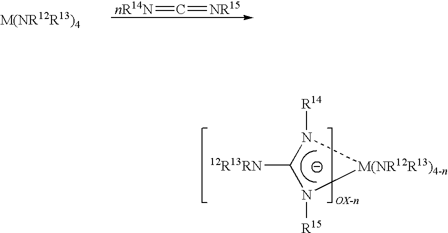

wherein: M is any of Zr, Hf, Ti, or Si; each of R¹², R¹³, R¹⁴ and R¹⁵ may be the same as or different from the others, and each is independently selected from among hydrogen, C₁-C₁₂ alkyl, C₃-C₁₀ cycloalkyl, C₂-C₈ alkenyl (e.g., vinyl, allyl, etc.), C₁-C₁₂ alkylsilyl (including monoalkylsilyl, dialkylsilyl and trialkylsilyl), C₆-C₁₀ aryl, —(CH₂)ₓNR′R″, —(CH₂)ₓOR″′ and —NR′R″, wherein x=1, 2 or 3, and R′, R″ and R″′ may be the same as or different from one another, and each is independently selected from H and C₁-C₁₂ alkyl; and n is from 1 to 4, inclusive.

In another aspect, the invention relates to a metal precursor compound, of the formula

X—M(NR₂)₃

wherein:
M is selected from among Hf, Zr and Ti;
X is selected from among: C₁-C₁₂ alkoxy, carboxylates; beta-diketonates, beta-diketiminates, and beta-diketoiminates; and

each R can be the same as or different from others, and is independently selected from among C₁-C₁₂ alkyl.

Another aspect of the invention relates to a method of forming a metal oxide or metal silicate film on a substrate, wherein the metal oxide or metal silicate film is of the formula MO₂ or MSiO₄, respectively, wherein M is a metal selected from among hafnium, zirconium, and titanium, said method comprising contacting said substrate with a precursor vapor composition comprising a precursor of the formula

X—M(NR₂)₃

wherein:
M is selected from among Hf, Zr and Ti;
X is selected from among: C₁-C₁₂ alkoxy, carboxylates; beta-diketonates, beta-diketiminates, and beta-diketoiminates; and

each R can be the same as or different from others, and is independently selected from among C₁-C₁₂ alkyl.

The invention in a further aspect relates to a method of making a Group IVB precursor having the formula X—M(NR₂)₃

wherein:
M is selected from among Hf, Zr and Ti;
X is selected from among: C₁-C₁₂ alkoxy (e.g., methoxy, ethoxy, proproxy, butoxy, etc.), carboxylates (e.g., formate, acetate, etc.); beta-diketonates (e.g., acac, thd, tod, etc.), beta-diketiminates, beta-diketoiminates, and the like; and
each R can be the same as or different from others, with each being independently selected from among C₁-C₁₂ alkyl,
said method comprising conducting the chemical reaction

M(NR₂)₄+HX→XM(NR₂)₃+HNR₂,

wherein M, X and Rs are as set out above.

The invention in another aspect relates to a Group IVB supply package, comprising a precursor storage and delivery vessel having an interior volume containing a Group IVB precursor having the formula X—M(NR₂)₃

wherein:
M is selected from among Hf, Zr and Ti;
X is selected from among: C₁-C₁₂ alkoxy (e.g., methoxy, ethoxy, proproxy, butoxy, etc.), carboxylates (e.g., formate, acetate, etc.); beta-diketonates (e.g., acac, thd, tod, etc.), beta-diketiminates, beta-diketoiminates, and the like; and
each R can be the same as or different from others, with each being independently selected from among C₁-C₁₂ alkyl.

Yet another aspect of the invention relates to a zirconium precursor for vapor deposition of zirconium-containing films, said precursor comprising a zirconium central atom, and ligands coordinated to the zirconium central, in which each of the ligands coordinated to the zirconium central atom is either an amine or diamine ligand, with at least one of such coordinated ligands being diamine, and wherein each of said amine and diamine ligands is substituted or unsubstituted, and when substituted comprises C₁-C₈ alkyl substituents, each of which may be the same as or different from others in the zirconium precursor.

A further aspect of the invention relates to a zirconium precursor selected from those of the formula

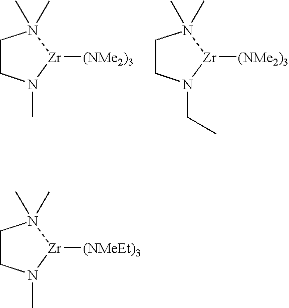

In another aspect, the invention relates to a method of making a zirconium precursor including amine and diamine functionality, comprising reacting a tetrakis amino zirconium compound with an N-substituted ethylene diamine compound, to yield the zirconium precursor including amine and diamine functionality. Aminoethylalkoxy compounds could also be used for making similar compounds.

A further aspect of the invention relates to a method of forming a zirconium-containing film on a substrate, comprising volatilizing a zirconium precursor compound to form a zirconium precursor vapor, and contacting the zirconium precursor vapor with a substrate to deposit the zirconium-containing film thereon, wherein the zirconium precursor comprises a precursor selected from among (I) and (II):

(I) a precursor comprising a zirconium central atom, and ligands coordinated to the zirconium central, in which each of the ligands coordinated to the zirconium central atom is either an amine or diamine ligand, with at least one of such coordinated ligands being diamine, and wherein each of said amine and diamine ligands is substituted or unsubstituted, and when substituted comprises C₁-C₈ alkyl substituents, each of which may be the same as or different from others in the zirconium precursor; and
(II) precursors of the formulae:

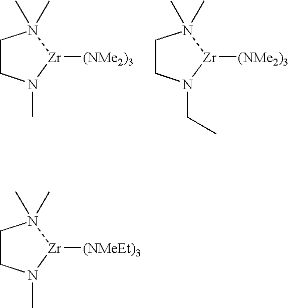

In a further aspect, the invention relates to a zirconium precursor supply package, comprising a precursor storage and delivery vessel having an interior volume containing a precursor selected from among (I) and (II):

(I) a precursor comprising a zirconium central atom, and ligands coordinated to the zirconium central, in which each of the ligands coordinated to the zirconium central atom is either an amine or diamine ligand, with at least one of such coordinated ligands being diamine, and wherein each of said amine and diamine ligands is substituted or unsubstituted, and when substituted comprises C₁-C₈ alkyl substituents, each of which may be the same as or different from others in the zirconium precursor; and
(II) precursors of the formulae:

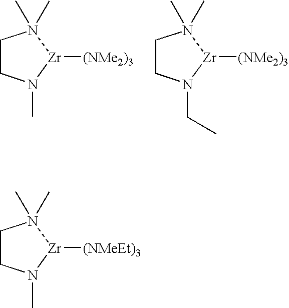

Another aspect of the invention relates to a metal precursor selected from among precursors of the formulae (A), (B), (C) and (D):

R³ₙM[N(R¹R⁴)(CR⁵R⁶)ₘN(R²)]_{OX-n} (A)

R³ₙM[E(R¹)(CR⁵R⁶)ₘN(R²)]_{OX-n} (B)

R³ₙM[(R²R^{3′}C═CR⁴)(CR⁵R⁶)ₘN(R¹)]_{OX-n} (C)

R³ₙM[E(CR⁵R⁶)ₘN(R¹R²)]_{OX-n} (D)

wherein:
each of R¹, R², R³, R^{3′}, R⁴, R⁵ and R⁶ may be the same as or different from the others, and is independently selected from among H, C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of the metal M;
n is an integer having a value of from 0 to OX;
m is an integer having a value of from 1 to 6;

### M is Ti, Zr or Hf; and

### E is O or S.

According to a further aspect, the invention relates to a method of forming a zirconium-containing film on a substrate, comprising volatilizing a zirconium precursor compound to form a zirconium precursor vapor, and contacting the zirconium precursor vapor with a substrate to deposit the zirconium-containing film thereon, wherein the zirconium precursor comprises a precursor selected from the group consisting of precursors of the formulae (A), (B), (C) and (D):

R³ₙM[N(R¹R⁴)(CR⁵R⁶)ₘN(R²)]_{OX-n} (A)

R³ₙM[E(R¹)(CR⁵R⁶)ₘN(R²)]_{OX-n} (B)

R³ₙM[(R²R^{3′}C═CR⁴)(CR⁵R⁶)ₘN(R¹)]_{OX-n} (C)

R³ₙM[E(CR⁵R⁶)ₘN(R¹R²)]_{OX-n} (D)

wherein:
each of R¹, R², R³, R^{3′}, R⁴, R⁵ and R⁶ may be the same as or different from the others, and is independently selected from among H, C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of the metal M;
n is an integer having a value of from 0 to OX;
m is an integer having a value of from 1 to 6;

### M is Ti, Zr or Hf; and

### E is O or S.

Another aspect of the invention relates to a zirconium precursor supply package, comprising a precursor storage and delivery vessel having an interior volume containing a precursor selected from the group consisting of precursors of the formulae (A), (B), (C) and (D):

R³ₙM[N(R¹R⁴)(CR⁵R⁶)ₘN(R²)]_{OX-n} (A)

R³ₙM[E(R¹)(CR⁵R⁶)ₘN(R²)]_{OX-n} (B)

R³ₙM[(R²R^{3′}C═CR⁴)(CR⁵R⁶)ₘN(R¹)]_{OX-n} (C)

R³ₙM[E(CR⁵R⁶)ₘN(R¹R²)]_{OX-n} (D)

wherein:
each of R¹, R², R³, R^{3′}, R⁴, R⁵ and R⁶ may be the same as or different from the others, and is independently selected from among H, C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of the metal M;
n is an integer having a value of from 0 to OX;
m is an integer having a value of from 1 to 6;

### M is Ti, Zr or Hf; and

### E is O or S.

A further aspect of the invention relates to a zirconium precursor, selected from the group consisting of:

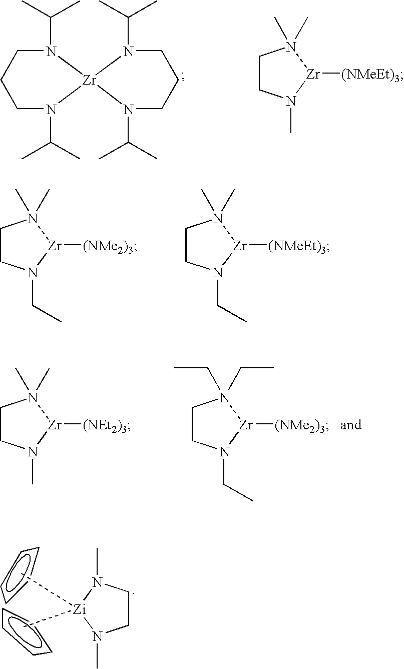

Another aspect of the invention relates to a titanium precursor, selected from the group consisting of TI-1 to TI-5:

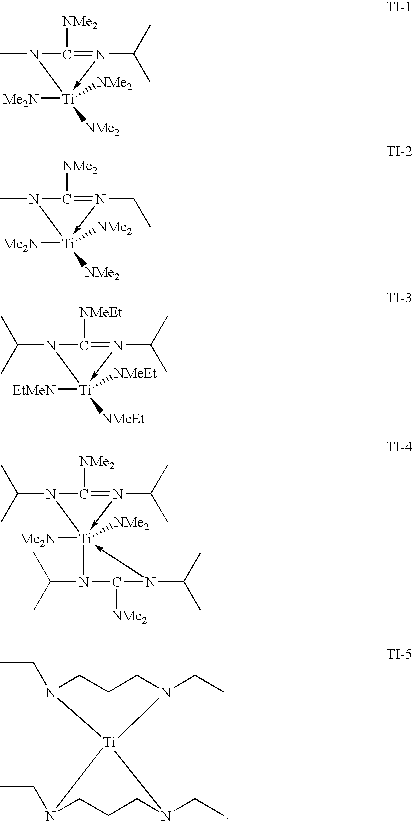

Yet another aspect of the invention relates to a Group IV metal complex of the formula

(C₅R¹R²R³R⁴R⁵)ₙMR₄₋ₙ

wherein each of R¹, R², R³, R⁴ and R⁵ can be the same as or different from the others, and each is independently selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
each R can be the same as or different from the others and each is independently selected from among C₁-C₆ alkyl, C₁-C₆ alkoxy, C₆-C₁₄ aryl, silyl, C₃-C₁₈ alkylsilyl, C₁-C₆ fluoroalkyl, amide, C₁-C₁₂ diamides, C₁-C₁₂ dialkoxides, aminoalkyl, alkoxyalkyl, aryloxyalkyl, imidoalkyl, hydrogen and acetylalkyl;
M is titanium, zirconium, hafnium or silicon; and
n is an integer having a value of from 0 to 4 inclusive.

In a further aspect, the invention relates to a method of making a Group IV metal precursor comprising the following reaction scheme:

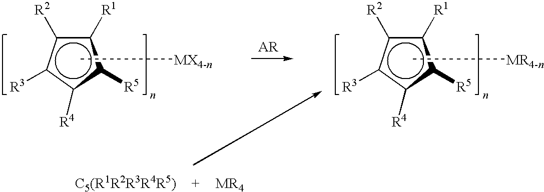

wherein each of R¹, R², R³, R⁴ and R⁵ can be the same as or different from the others, and each is independently selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
each R can be the same as or different from the others and each is independently selected from among C₁-C₆ alkyl, C₁-C₆ alkoxy, C₆-C₁₄ aryl, silyl, C₃-C₁₈ alkylsilyl, C₁-C₆ fluoroalkyl, amide, C₁-C₁₂ diamides, C₁-C₁₂ dialkoxides, aminoalkyl, alkoxyalkyl, aryloxyalkyl, imidoalkyl, hydrogen and acetylalkyl;
X is halogen;
n is an integer having a value of from 0 to 4 inclusive;
A is an alkaloid metal; and
M is titanium, zirconium, hafnium or silicon.

Still another aspect of the invention relates to a Zr precursor comprising

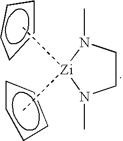

A further aspect of the invention relates to a Ti guanidinate of the formula

(R⁵)_{OX-n}Ti[R¹NC(NR²R³)NR⁴]ₙ

wherein:
each of R¹, R², R³, R⁴ and R⁵ can be the same as or different from the others, and each is independently selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
n is an integer having a value of from 0 to 4; and
OX is the oxidation state of the Ti metal center.

The invention in another aspect relates to a titanium diamide, selected from compounds of the formulae:

(R¹N(CR²R³)ₘNR⁴)_{OX-n/2}Tiₙ (I)

wherein
each of R¹, R², R³ and R⁴ can be the same as or different from the others, and each is independently selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
m is an integer having a value of from 2 to 6;
n is an integer having a value of from 0 to OX; and
OX is the oxidation state of the Ti metal center, and

(R¹N(CR²)ₘNR⁴)_{OX-n/2}Tiₙ (II)

wherein
each of R¹, R², R³ and R⁴ can be the same as or different from the others, and each is independently selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
m is an integer having a value of from 2 to 6;
n is an integer having a value of from 0 to OX; and
OX is the oxidation state of the Ti metal center.

A still further aspect of the invention relates to a method of stabilization of a metal amide, comprising addition thereto of at least one amine.

A further aspect of the invention relates to a method of stabilization of a metal amide precursor delivered to a substrate for deposition thereon of metal deriving from the metal amide, by addition of at least one amine to the metal amide precursor prior to or during said delivery.

As used herein, the term “film” refers to a layer of deposited material having a thickness below 1000 micrometers, e.g., from such value down to atomic monolayer thickness values. In various embodiments, film thicknesses of deposited material layers in the practice of the invention may for example be below 100, 10, or 1 micrometers, or in various thin film regimes below 200, 100, or 50 nanometers, depending on the specific application involved. As used herein, the term “thin film” means a layer of a material having a thickness below 1 micrometer.

It is noted that as used herein and in the appended claims, the singular forms “a”, “and”, and “the” include plural referents unless the context clearly dictates otherwise.

As used herein, the identification of a carbon number range, e.g., in C₁-C₁₂ alkyl, is intended to include each of the component carbon number moieties within such range, so that each intervening carbon number and any other stated or intervening carbon number value in that stated range, is encompassed, it being further understood that sub-ranges of carbon number within specified carbon number ranges may independently be included in smaller carbon number ranges, within the scope of the invention, and that ranges of carbon numbers specifically excluding a carbon number or numbers are included in the invention, and sub-ranges excluding either or both of carbon number limits of specified ranges are also included in the invention. Accordingly, C₁-C₁₂ alkyl is intended to include methyl, ethyl, propyl, butyl, pentyl, hexyl, heptyl, octyl, nonyl, decyl, undecyl and dodecyl, including straight chain as well as branched groups of such types. It therefore is to be appreciated that identification of a carbon number range, e.g., C₁-C₁₂, as broadly applicable to a substituent moiety, enables, in specific embodiments of the invention, the carbon number range to be further restricted, as a sub-group of moieties having a carbon number range within the broader specification of the substituent moiety. By way of example, the carbon number range e.g., C₁-C₁₂ alkyl, may be more restrictively specified, in particular embodiments of the invention, to encompass sub-ranges such as C₁-C₄ alkyl, C₂-C₈ alkyl, C₂-C₄ alkyl, C₃-C₅ alkyl, or any other sub-range within the broad carbon number range.

Other aspects, features and embodiments of the invention will be more fully apparent from the ensuing disclosure and appended claims.

### BRIEF DESCRIPTION OF THE DRAWINGS

FIG. 1 is a schematic representation of a material storage and dispensing package containing a precursor, according to one embodiment of the present invention.

### DETAILED DESCRIPTION OF THE INVENTION, AND PREFERRED EMBODIMENTS THEREOF

The present invention relates to zirconium, hafnium, titanium and silicon precursors. These precursors are useful for atomic layer deposition (ALD) and chemical vapor deposition (CVD) of corresponding zirconium-containing, hafnium-containing, titanium-containing and silicon-containing films, respectively. For example, zirconium precursors of the invention can be employed to deposit zirconium oxide and zirconium silicate on substrates in a highly efficient manner.

In one embodiment, the precursors of the invention include compounds of the formulae:
M(NR₂)₄, wherein each R may be the same as or different from the others and each is independently selected from among hydrogen, C₁-C₁₂ alkyl, C₃-C₁₀ cycloalkyl, C₂-C₈ alkenyl, C₁-C₁₂ alkylsilyl, C₆-C₁₀ aryl, —(CH₂)ₓNR′R″, —(CH₂)ₓOR″′ and —NR′R″, wherein x=1, 2 or 3, and R′, R″ and R″′ may be the same as or different from one another, and each is independently selected from H and C₁-C₁₂ alkyl;
   (R¹NC(R³R⁴)ₘNR²)_{(OX-n)/2}MXₙ, wherein R¹, R², R³, R⁴ and X may be the same as or different from one another and each is independently selected from among hydrogen, C₁-C₁₂ alkyl, C₃-C₁₀ cycloalkyl, C₂-C₆ alkenyl, C₁-C₁₂ alkylsilyl, C₆-C₁₀ aryl, —(CH₂)ₓNR′R″, —(CH₂)ₓOR″′ and —NR′R″, wherein x=1, 2 or 3, and R′, R″ and R″′ can be the same as or different from one another, and each is independently selected from H and C₁-C₁₂ alkyl, wherein the subscripts 1 through 12 in the sequence of carbon numbers designates the number of carbon atoms in the alkyl substituent; m is an integer having a value of from 1 to 6, and in addition, X can be selected from among C₁-C₁₂ alkoxy, carboxylates; beta-diketonates, beta-diketiminates, and beta-diketoiminates, guanidinates, amidinates and isoureates; and further wherein C(R³R⁴)ₘ can be alkylene; OX is the oxidation state of the metal M; n is an integer having a value of from 0 to OX; m is an integer having a value of from 1 to 6;
   M(E)₂(OR³)₂ wherein E is a substituted dionate, each R³ is the same as or different from the other, and each is independently selected from among C₁-C₁₂ alkyl, C₃-C₁₀ cycloalkyl, C₂-C₈ alkenyl, C₁-C₁₂ alkylsilyl, C₆-C₁₀ aryl, —(CH₂)ₓ(NR′R″, —(CH₂)ₓOR″′ and —NR′R″, wherein x=1, 2 or 3, and R′, R″ and R″′ may be the same as or different from one another, and each is independently selected from H and C₁-C₁₂ alkyl;
   M(OR³)₄ wherein each R³ is the same as or different from the other, and each is independently selected from among C₁-C₁₂ alkyl, C₃-C₁₀ cycloalkyl, C₂-C₈ alkenyl, C₁-C₁₂ alkylsilyl, C₆-C₁₀ aryl, —(CH₂)ₓNR′R″, —(CH₂)ₓOR″′ and —NR′R″, wherein x=1, 2 or 3, and R′, R″ and R″′ may be the same as or different from one another, and each is independently selected from H and C₁-C₁₂ alkyl;
   M(OPr-i)₄-IPA wherein IPA is isopropyl alcohol and OPr-i is isopropoxy;
   (R⁶R⁷N)₂M(R⁸NC(R³R⁴)ₘNR⁹) wherein R³, R⁴, R⁶ and R⁷, R⁸ and R⁹ may be the same as or different from one another and each is independently selected from among hydrogen, C₁-C₁₂ alkyl, C₃-C₁₀ cycloalkyl, C₂-C₈ alkenyl, C₁-C₁₂ alkylsilyl, C₆-C₁₀ aryl, —(CH₂)ₓNR′R″, —(CH₂)ₓOR″′ and —NR′R″, wherein x=1, 2 or 3, and R′, R″ and R″′ may be the same as or different from one another, and each is independently selected from H and C₁-C₁₂ alkyl, and further wherein both of R⁶ or R⁷ groups of respective amino nitrogen atoms in the (R⁶R⁷N)₂ moiety can together be alkylene, and C(R³R⁴)ₘ in the (R⁸NC(R³R⁴)ₘNR⁹) moiety can be alkylene; and m is an integer having a value of from 1 to 6; and
   compounds selected from among (amidinate)_{OX-n}MXₙ, (guanidinate)_{OX-n}MXₙ and (isoureate)_{OX-n}MXₙ, wherein each X can be the same as or different from the others and each is independently selected from among hydrogen, C₁-C₁₂ alkyl, C₃-C₁₀ cycloalkyl, C₂-C₆ alkenyl, C₁-C₁₂ alkylsilyl, C₆-C₁₀ aryl, —(CH₂)ₓ(NR′R″, —(CH₂)ₓOR″′ and NR′R″, wherein x=1, 2 or 3, and R′, R″ and R″′ can be the same as or different from one another, and each is independently selected from H and C₁-C₁₂ alkyl, wherein the subscripts 1 through 12 in the sequence of carbon numbers designates the number of carbon atoms in the alkyl substituent; m is an integer having a value of from 1 to 6, and in addition, X can be selected from among C₁-C₁₂ alkoxy, carboxylates; beta-diketonates, beta-diketiminates, and beta-diketoiminates, guanidinates, amidinates and isoureates; OX is the oxidation state of the metal M; n is an integer having a value of from 0 to OX; m is an integer having a value of from 1 to 6; and M is Ti, Zr, H or Si.

The precursors of the invention in another embodiment include those of the following formulae:

M(NR₂)₄, wherein each R may be the same as or different from the others and each is independently selected from among hydrogen, C₁-C₁₂ alkyl, C₃-C₁₀ cycloalkyl, C₂-C₈ alkenyl (e.g., vinyl, allyl, etc.), C₁-C₁₂ alkylsilyl (including monoalkylsilyl, dialkylsilyl and trialkylsilyl), C₆-C₁₀ aryl, —(CH₂)ₓNR′R″, —(CH₂)ₓOR″′ and —NR′R″, wherein x=1, 2 or 3, and R′, R″ and R″′ may be the same as or different from one another, and each is independently selected from H and C₁-C₁₂ alkyl;

(R¹NCH₂CH₂NR²)₂M wherein R¹ and R² may be the same as or different from one another and each is independently selected from among hydrogen, C₁-C₁₂ alkyl, C₃-C₁₀ cycloalkyl, C₂-C₈ alkenyl (e.g., vinyl, allyl, etc.), C₁-C₁₂ alkylsilyl (including monoalkylsilyl, dialkylsilyl and trialkylsilyl), C₆-C₁₀ aryl, —(CH₂)ₓNR′R″, —(CH₂)ₓOR″′ and —NR′R″, wherein x=1, 2 or 3, and R′, R″ and R″′ may be the same as or different from one another, and each is independently selected from H and C₁-C₁₂ alkyl, wherein the subscripts 1 through 12 in the sequence of carbon numbers designates the number of carbon atoms in the alkyl substituent;

M(β-diketonate)₂(OR³)₂ wherein each R³ is the same as or different from the other, and each is independently selected from among C₁-C₁₂ alkyl, C₃-C₁₀ cycloalkyl, C₂-C₈ alkenyl (e.g., vinyl, allyl, etc.), C₁-C₁₂ alkylsilyl (including monoalkylsilyl, dialkylsilyl and trialkylsilyl), C₆-C₁₀ aryl, —(CH₂)ₓNR′R″, —(CH₂)ₓOR″′ and —NR′R″, wherein x=1, 2 or 3, and R′, R″ and R″′ may be the same as or different from one another, and each is independently selected from H and C₁-C₁₂ alkyl, and preferably from among i-propyl and t-butyl (i-propyl being isopropyl and t-butyl being tertiary butyl);

M(OR³)₄ wherein each R³ is the same as or different from the other, and each is independently selected from among C₁-C₁₂ alkyl, C₃-C₁₀ cycloalkyl, C₂-C₈ alkenyl (e.g., vinyl, allyl, etc.), C₁-C₁₂ alkylsilyl (including monoalkylsilyl, dialkylsilyl and trialkylsilyl), C₆-C₁₀ aryl, —(CH₂)ₓNR′R″, —(CH₂)ₓOR″′ and —NR′R″, wherein x=1, 2 or 3, and R′, R″ and R″′ may be the same as or different from one another, and each is independently selected from H and C₁-C₁₂ alkyl, and preferably from among i-propyl and t-butyl;

M(OPr-i)₄-IPA wherein IPA is isopropyl alcohol and OPr-i is isopropoxy;

(R⁴R⁵N)₂M(R⁶NCH₂CH₂NR⁷) wherein R⁴, R⁵, R⁶ and R⁷ may be the same as or different from one another and each is independently selected from among hydrogen, C₁-C₁₂ alkyl, C₃-C₁₀ cycloalkyl, C₂-C₈ alkenyl (e.g., vinyl, allyl, etc.), C₁-C₁₂ alkylsilyl (including monoalkylsilyl, dialkylsilyl and trialkylsilyl), C₆-C₁₀ aryl, —(CH₂)ₓNR′R″, —(CH₂)ₓOR″′ and —NR′R″, wherein x=1, 2 or 3, and R′, R″ and R″′ may be the same as or different from one another, and each is independently selected from H and C₁-C₁₂ alkyl; and

compounds selected from among (amidinate)_{OX-n}MXₙ, (guanidinate)_{OX-n}MXₙ and (isoureate)_{OX-n}MXₙ, wherein each X can be the same as or different from the others and each is independently selected from among hydrogen, C₁-C₁₂ alkyl, C₃-C₁₀ cycloalkyl, C₂-C₆ alkenyl (e.g., vinyl, allyl, etc.), C₁-C₁₂ alkylsilyl (including monoalkylsilyl, dialkylsilyl, and trialkylsilyl), C₆-C₁₀ aryl, —(CH₂)ₓNR′R″, —(CH₂)ₓOR″′ and —NR′R″, wherein x=1, 2 or 3, and R′, R″ and R″′ can be the same as or different from one another, and each is independently selected from H and C₁-C₁₂ alkyl, wherein the subscripts 1 through 12 in the sequence of carbon numbers designates the number of carbon atoms in the alkyl substituent; m is an integer having a value of from 1 to 6, and in addition, X can be selected from among C₁-C₁₂ alkoxy, carboxylates; beta-diketonates, beta-diketiminates, and beta-diketoiminates, guanidinates, amidinates and isoureates; OX is the oxidation state of the metal M; n is an integer having a value of from 0 to OX; m is an integer having a value of from 1 to 6,

wherein M is selected from the group consisting of zirconium, hafnium, titanium and silicon.

In one specific embodiment, the precursors of the invention are selected from among those of the above formulae, wherein each of the respective substituents R, R¹, R², R³, R⁴, R⁵, R⁶, R⁷, R⁸, R⁹, R¹⁰, R¹¹, R¹², R¹³, R′, R″ and R″′ can be the same as or different from the others, and each is independently selected from among C₁-C₁₂ alkyl.

In another specific aspect, the present invention contemplates zirconium precursors having utility for forming Zr-containing thin films, e.g., for high k dielectric applications, selected from among those of the following formulae:

Zr(NMe₂)₄;

(R¹NCH₂CH₂NR²)₂Zr wherein R¹ and R² may be the same as or different from one another and each is independently selected from among C₁-C₁₂ alkyl;
Zr(E)₂(OR³)₂ wherein E is a substituted dionate, e.g., a beta-diketonate, and each R³ is the same as or different from the other, and each is independently selected from among i-propyl and t-butyl;
Zr(OR³)₄ wherein each R³ is the same as or different from the other, and each is independently selected from among i-propyl and t-butyl;
Zr(OPr-i)₄-IPA wherein IPA is isopropyl alcohol and OPr-i is isopropoxy;
(R⁴R⁵N)₂Zr(R⁶NCH₂CH₂NR⁷) wherein R⁴, R⁵, R⁶ and R⁷ may be the same as or different from one another and each is independently selected from among C₁-C₁₂ alkyl; and
(guanidinate)Zr(NR⁸R⁹)₃ wherein guanidinate may be substituted or unsubstituted, R⁸ and R⁹ may be the same as or different from one another and each is independently selected from among C₁-C₁₂ alkyl.

The substituted dionato ligand, e.g., β-diketonato ligand, in the precursor compounds of the formula Zr(E)₂(OR³)₂ wherein E is substituted dionato, may be of any suitable type providing a precursor of appropriate character for the specific metal species M in such compounds. Illustrative β-diketonato ligand species that may be employed in various precursor compounds of the invention are set out in Table I below:

TABLE I

| β-diketonato ligand | Abbreviation |
|---|---|
| 2,2,6,6-tetramethyl-3,5-heptanedionato | thd |
| 1,1,1-trifluoro-2,4-pentanedionato | tfac |
| 1,1,1,5,5,5-hexafluoro-2,4-pentanedionato | hfac |
| 6,6,7,7,8,8,8-heptafluoro-2,2-dimethyl-3,5-octanedionato | fod |
| 2,2,7-trimethyl-3,5-octanedionato | tod |
| 1,1,1,5,5,6,6,7,7,7-decafluoro-2,4-heptanedionato | dfhd |
| 1,1,1-trifluoro-6-methyl-2,4-heptanedionato | tfmhd |

The precursors of the invention can be readily synthesized, within the skill of the art, based on the disclosure herein. In one embodiment, metal mono-guanidinate precursors of the invention can be synthesized by reaction involving carbodiimide insertion in tetrakis amides, as set out below:

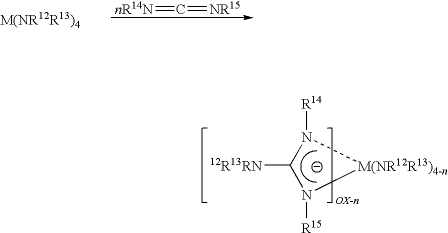

wherein: M is any of Zr, Hf, Ti, or Si; each of R¹², R¹³, R¹⁴ and R¹⁵ may be the same as or different from the others, and each is independently selected from among hydrogen, C₁-C₁₂ alkyl, C₃-C₁₀ cycloalkyl, C₂-C₈ alkenyl (e.g., vinyl, allyl, etc.), C₁-C₁₂ alkylsilyl (including monoalkylsilyl, dialkylsilyl and trialkylsilyl), C₆-C₁₀ aryl, —(CH₂)ₓNR′R″, —(CH₂)ₓOR″′ and —NR′R″, wherein x=1, 2 or 3, and R′, R″ and R″′ may be the same as or different from one another, and each is independently selected from H and C₁-C₁₂ alkyl; and n is from 1 to 4, inclusive.

By way of a specific example, the foregoing synthesis reaction can be carried out wherein M is zirconium, and each of R¹⁰, R¹¹, R¹² and R¹³ is C₁-C₁₂ alkyl, to form zirconium mono-, di-, tri- and tetra-guanidinates, wherein the non-guanidinate ligands are dialkylamido, e.g., dimethylamido, diethylamido or diisopropylamido. The guanidinate may be substituted or unsubstituted.

Other syntheses of an analogous character within the scope of the invention can be carried out to yield precursors of the invention.

As discussed in the background section hereof, previously employed Zr precursors have produced films of poor conformality at higher deposition temperatures and high carbon incorporation at lower deposition temperatures. Such poor conformality is the result of the precursor being too reactive at higher temperatures, which drives the deposition kinetics to a mass-transport regime yielding poor conformality. This poor conformality is avoided by lower deposition temperatures but the temperatures required for such acceptable conformality are not sufficient to avoid carbon incorporation.

The precursors of the present invention yield films of good conformality with low levels of carbon impurities, and are readily depositable by techniques such as ALD and CVD.

In ALD and CVD vapor deposition processes, the precursor is contacted with a substrate under conditions producing formation of a zirconium-containing, hafnium-containing, titanium-containing or silicon-containing film, depending on the specific precursor employed. The deposition process may be carried out under any suitable process conditions, involving appropriate pressures, temperatures, concentrations, flow rates, etc., as may be readily determined within the skill of the art, based on empirical variation of the process conditions and characterization of the resulting films, to determine a suitable process condition envelope for the specific film formation involved.

In one preferred embodiment, a precursor of the invention is contacted with a substrate in the presence of a co-reactant selected from among oxygen, ozone, dinitrogen oxide and water.

In another preferred embodiment, a precursor of the invention is contacted with a substrate in the presence of a plasma mixture comprising a first plasma mixture component selected from the group consisting of oxygen, ozone, dinitrogen oxide and water, and a second plasma mixture component selected from the group consisting of argon, helium and nitrogen.

In particular applications, utilizing zirconium precursors of the invention, ALD and CVD processes may be employed to deposit zirconium dioxide or zirconium silicate, e.g., in the manufacture of a microelectronic device or other thin-film zirconium product.

It will be appreciated that zirconium silicate films can be deposited in the practice of the present invention, utilizing a zirconium precursor as well as a silicon precursor in the deposition process. More generally, the zirconium, hafnium, titanium and silicon precursors of the invention can be utilized in various combinations to produce resulting composite films, e.g., a zirconium titanate film.

Deposition processes utilizing the above-discussed precursors can be carried out in any suitable ambient environment. For example, the ambient environment may include a reducing atmosphere, an oxic gas environment, or a nitrogen-containing gaseous ambient, to produce a correspondingly desired product film on a substrate with which the precursor vapor is contacted.

Another aspect of the invention relates to packaged forms of the above-discussed precursors. For example, the precursor may be packaged in a precursor storage and dispensing package, wherein a useful quantity of the precursor is held, for dispensing thereof. The precursor as contained in such package may be in any suitable form.

For example, the precursor may be of a solid form, held in a finely divided state, e.g., in the form of powder, granules, pellets, etc., and retained in the storage and dispensing package, with the package including heating structure for selective input of the heat to the precursor in the vessel, for volatilization thereof. The resulting precursor vapor then may be dispensed through a dispensing valve and associated flow circuitry, for transport to a deposition reactor and contact with a substrate.

Alternatively, the precursor may be of a liquid form, retained in the storage and dispensing package for selective discharge of vapor deriving from the liquid, optionally with selective input of heat to the precursor liquid as described above in connection with solid precursor packaging, to generate a corresponding precursor vapor from such liquid.

As a still further alternative, the precursor may be retained in liquid form in the storage and dispensing package for selective discharge of the liquid, and subsequent volatilization thereof to form the precursor vapor for the vapor deposition process. Such liquid delivery technique can involve a storage and dispensing of the precursor in a neat liquid form, or, if the precursor is of a solid, liquid or semisolid form, the precursor can be dissolved or dispersed in a suitable solvent medium for such liquid delivery dispensing.

The solvent medium in which the precursor is dissolved or dispersed may be of any suitable type. Solvents potentially useful for such purpose include, without limitation, one or more solvent species selected from among hydrocarbon solvents, e.g., C₃-C₁₂ alkanes; C₂-C₁₂ ethers; C₆-C₁₂ aromatics; C₇-C₁₆ arylalkanes; C₁₀-C₂₅ arylcyloalkanes; and further alkyl-substituted forms of such aromatics, arylalkanes and arylcyloalkanes, wherein the further alkyl substituents in the case of multiple alkyl substituents may be the same as or different from one another and wherein each is independently selected from C1-C₈ alkyl; alkyl-substituted benzene compounds; benzocyclohexane (tetralin); alkyl-substituted benzocyclohexane; tetrahydrofuran; xylene; 1,4-tertbutyltoluene; tetrahydrofuran; 1,3-diisopropylbenzene; dimethyltetralin; amines; DMAPA; toluene; glymes; diglymes; triglymes; tetraglymes; octane; and decane.

The liquid delivery precursor composition may be volatilized in any suitable manner, such as by passage through a nebulizer, contacting of the precursor liquid with a vaporization element at elevated temperature, or in any other suitable manner producing a vapor of suitable character for contacting with the substrate and deposition of a film thereon.

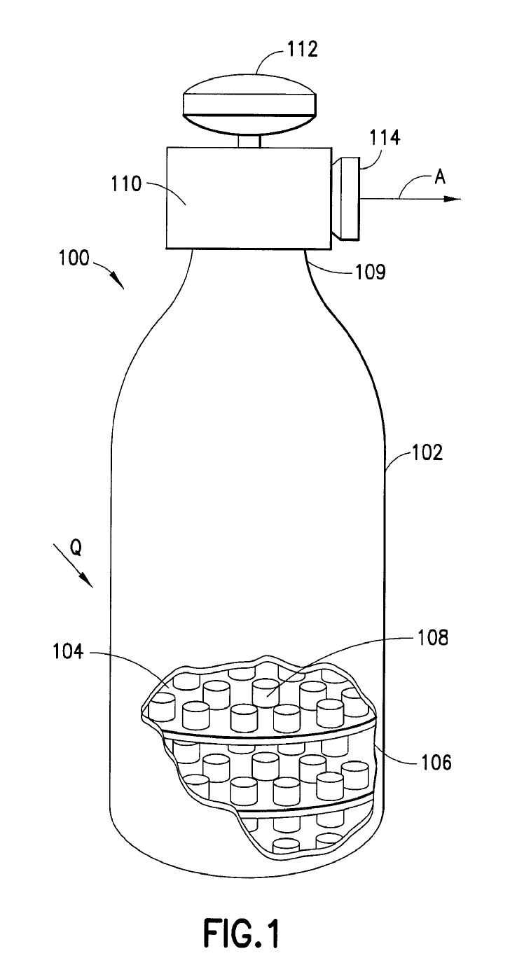

FIG. 1 is a schematic representation of a material storage and dispensing package 100 containing a zirconium precursor, according to one embodiment of the present invention, for use in solid delivery ALD or CVD applications.

The material storage and dispensing package 100 includes a vessel 102 that may for example be of generally cylindrical shape as illustrated, defining an interior volume 104 therein. In this specific embodiment, the precursor is a solid at ambient temperature conditions, and such precursor may be supported on surfaces of the trays 106 disposed in the interior volume 104 of the vessel, with the trays having flow passage conduits 108 associated therewith, for flow of vapor upwardly in the vessel to the valve head assembly, for dispensing in use of the vessel.

The solid precursor can be coated on interior surfaces in the interior volume of the vessel, e.g., on the surfaces of the trays 106 and conduits 108. Such coating may be effected by introduction of the precursor into the vessel in a vapor form from which the solid precursor is condensed in a film on the surfaces in the vessel. Alternatively, the precursor solid may be dissolved or suspended in a solvent medium and deposited on surfaces in the interior volume of the vessel by solvent evaporation. In yet another method the precursor may be melted and poured onto the surfaces in the interior volume of the vessel. For such purpose, the vessel may contain substrate articles or elements that provide additional surface area in the vessel for support of the precursor film thereon.

As a still further alternative, the solid precursor may be provided in granular or finely divided form, which is poured into the vessel to be retained on the top supporting surfaces of the respective trays 106 therein.

The vessel 102 has a neck portion 109 to which is joined the valve head assembly 110. The valve head assembly is equipped with a hand wheel 112 in the embodiment shown. The valve head assembly 110 includes a dispensing port 114, which may be configured for coupling to a fitting or connection element to join flow circuitry to the vessel. Such flow circuitry is schematically represented by arrow A in FIG. 1, and the flow circuitry may be coupled to a downstream ALD or chemical vapor deposition chamber (not shown in FIG. 1).

In use, the vessel 102 is heated, such input of heat being schematically shown by the reference arrow Q, so that solid precursor in the vessel is at least partially volatilized to provide precursor vapor. The precursor vapor is discharged from the vessel through the valve passages in the valve head assembly 110 when the hand wheel 112 is translated to an open valve position, whereupon vapor deriving from the precursor is dispensed into the flow circuitry schematically indicated by arrow A.

In lieu of solid delivery of the precursor, the precursor may be provided in a solvent medium, forming a solution or suspension. Such precursor-containing solvent composition then may be delivered by liquid delivery and flash vaporized to produce a precursor vapor. The precursor vapor is contacted with a substrate under deposition conditions, to deposit the metal on the substrate as a film thereon.

In one embodiment, the precursor is dissolved in an ionic liquid medium, from which precursor vapor is withdrawn from the ionic liquid solution under dispensing conditions.

As a still further alternative, the precursor may be stored in an adsorbed state on a suitable solid-phase physical adsorbent storage medium in the interior volume of the vessel. In use, the precursor vapor is dispensed from the vessel under dispensing conditions involving desorption of the adsorbed precursor from the solid-phase physical adsorbent storage medium.

Supply vessels for precursor delivery may be of widely varying type, and may employ vessels such as those commercially available from ATMI, Inc. (Danbury, Conn.) under the trademarks SDS, SAGE, VAC, VACSorb, and ProE-Vap, as may be appropriate in a given storage and dispensing application for a particular precursor of the invention.

The precursors of the invention thus may be employed to form precursor vapor for contacting with a substrate to deposit a thin film thereon, e.g., of zirconium, hafnium, titanium and/or silicon.

In one preferred aspect, the invention utilizes the precursor to conduct atomic layer deposition, yielding ALD films of superior conformality that are uniformly coated on the substrate with high step coverage, even on high aspect ratio structures.

Accordingly, the precursors of the present invention enable a wide variety of microelectronic devices, e.g., semiconductor products, flat panel displays, etc., to be fabricated with zirconium-containing, hafnium-containing, titanium-containing and/or silicon-containing films of superior quality.

Another aspect of the present invention relates to Group IVB precursors that are useful for deposition of metal oxide and metal silicate films, of the formula MO₂ and MSiO₄, wherein M is a metal selected from among hafnium, zirconium, and titanium. These Group IVB precursors are usefully employed as high k dielectric precursors for forming high k dielectric films on substrates such as wafers or other micro-electronic device structures, and may be deposited by chemical vapor deposition (CVD) or atomic layer deposition (ALD) on structures with high aspect ratio characteristics, to produce films with uniform thickness and superior conformality.

Such Group IVB precursors have the formula X—M(NR₂)₃ wherein:

M is selected from among Hf, Zr and Ti;
X is selected from among: C₁-C₁₂ alkoxy (e.g., methoxy, ethoxy, proproxy, butoxy, etc.), carboxylates (e.g., formate, acetate, etc.); beta-diketonates (e.g., acac, thd, tod, etc.), beta-diketiminates, beta-diketoiminates, and the like; and
each R can be the same as or different from others, with each being independently selected from among C₁-C₁₂ alkyl.

The Group IVB precursors of the formula X—M(NR₂)₃ can be readily synthesized by reactions such as M(NR₂)₄+HX→XM(NR₂)₃+HNR₂, wherein M, X and Rs are as set out above herein.

Carboxylate ligands useful in the foregoing precursors have the formula:

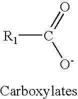

wherein:
R₁ is selected from the group consisting of hydrogen, C₁ to C₅ alkyl, C₃ to C₇ cycloalkyl, C₁-C₅ perfluoroalkyl, and C₆ to C₁₀ aryl.

Such Group IVB precursors have the formula X—M(NR₂)₃ wherein:

Beta-diketonate, beta-diketiminate and beta-diketoiminate ligands in the Group IVB precursors have the following formulae:

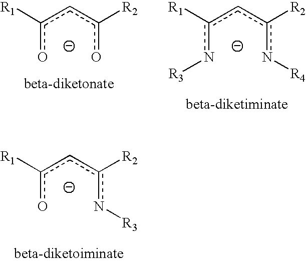

wherein:
each of R₁, R₂, R₃ and R₄ can be the same as or different from the others, and each is independently selected from the group consisting of C₁ to C₅ alkyl, C₃ to C₇ cycloalkyl, C₁ to C₅ perfluoroalkyl, and C₆ to C₁₀ aryl.

The above-described Group IVB precursors can be utilized for CVD and ALD processes including liquid delivery, or alternatively solid delivery, of the precursor.

For solid delivery, the precursor may be packaged in a suitable solid storage and vapor delivery vessel, in which the vessel is constructed and arranged to transmit to heat to the solid precursor in the vessel for volatilization thereof to form a precursor vapor that is selectively dispensed from the vessel and transmitted to the downstream CVD or ALD or other process. Suitable solid delivery vessels of such type are commercially available from ATMI (Danbury, Conn., USA) under the trademark ProE-Vap.

To form metal silicate films, the Group IVB precursors may be employed with suitable silicon precursors, or alternatively, such Group IVB precursors can be substituted at R groups thereof with silicon-containing functionality, e.g., alkylsilyl groups.

In liquid delivery applications, the precursor may be dissolved or suspended in a suitable solvent medium. The solvent medium for such purpose may comprise a single-component or alternatively a multi-component solvent composition which then is volatilized to form precursor vapor that is transported, e.g., by suitable flow circuitry, to the downstream fluid-utilization facility. For such purpose, any suitable solvent medium may be employed, that is compatible with the precursor and volatilizable to produce precursor vapor of appropriate character.

In a further aspect, the invention relates to zirconium precursors useful in chemical vapor deposition and atomic layer deposition, in which each of the ligands coordinated to the zirconium central atom is either an amine or diamine moiety, with at least one of such ligands being diamine. Each of the amine and diamine ligands is substituted or unsubstituted, and when substituted comprises C₁-C₈ alkyl substituents, each of which may be the same as or different from others in the zirconium precursor. Such precursors can be made by a synthesis reaction in which one of the amine groups on a tetrakis amino zirconium molecule is replaced with a diamine moiety.

In one preferred embodiment, the zirconium precursor comprises a five-coordinate zirconium precursor, selected from among precursors of the formula:

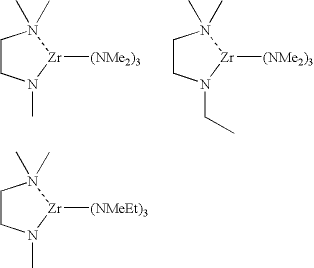

Such precursors can be formed by reacting tetrakis dimethylamino zirconium (TDMAZ) with a diamine such as dimethylethyl ethylenediamine (DMEED), e.g., according to the following reaction:

R³₄M+(R¹R⁴)NC(R⁵R⁶)ₘN(R²)H→R³nM[(R¹R⁴)NC(R⁵R⁶)ₘN(R²)]_{OX-n}

each of R¹, R², R³, R⁴, R⁵ and R⁶ may be the same as or different from the others, and is independently selected from among H, C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of the metal M;
n is an integer having a value of from 0 to OX;
m is an integer having a value of from 1 to 6;

### M is Ti, Zr or Hf; and Si.

Such reaction may for example be carried out in a reaction volume in which the TDMAZ is dissolved in toluene and one equivalent of dimethylethyl ethylenediamine.is added, followed by refluxing of the reaction mixture for several hours, whereby the heat of reflux drives the reaction to completion. As the dimethylamine is replaced with DMEED the free dimethylamine is liberated as a gas from the reaction volume. The diamine ligand thereby forms a dative bond with the metal center resulting in a five coordinate zirconium molecule of enhanced air stability, in relation to the tetrakis dimethylamino zirconium. The five coordinate zirconium precursor can be utilized as a liquid precursor, to carry out CVD are ALD processes involving liquid delivery of such precursor.

The foregoing synthetic technique can also be employed to form corresponding five coordinate zirconium precursors using tetrakisaminozirconium compounds such as tetrakis ethylmethylamino zirconium (TEMAZ) and tetrakis diethylamino zirconium (TDEAZ).

Another aspect of the invention relates to metal precursors, of the formulae (A), (B), (C) and (D):

R³ₙM[N(R¹R⁴)(CR⁵R⁶)ₘN(R²)]_{OX-n} (A)

R³ₙM[E(R¹)(CR⁵R⁶)ₘN(R²)]_{OX-n} (B)

R³ₙM[(R²R^{3′}C═CR⁴)(CR⁵R⁶)ₘN(R¹)]_{OX-n} (C)

R³ₙM[E(CR⁵R⁶)ₘN(R¹R²)]_{OX-n} (D)

wherein:
each of R¹, R², R³, R^{3′}, R⁴, R⁵ and R⁶ may be the same as or different from the others, and is independently selected from among H, C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of the metal M;
n is an integer having a value of from 0 to OX;
m is an integer having a value of from 1 to 6;

### M is Ti, Zr or Hf; and

### E is O or S.

These precursors have the following formulae:

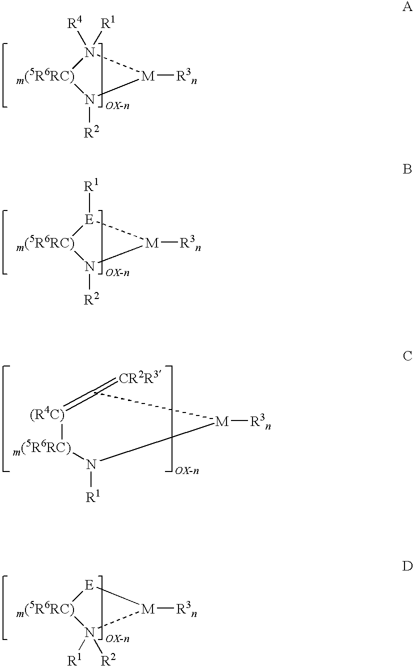

The foregoing precursors of formulae (A)-(D) exhibit good thermal stability and transport properties for CVD/ALD applications.

The aminoalkyl, alkoxyalkyl, aryloxyalkyl, imidoalkyl, and acetylalkyl groups useful as substituents for the precursors (A)-(D) include groups having the following formulae:

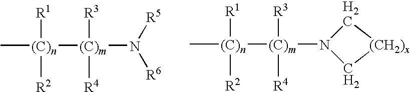

aminoalkyls
   wherein: the methylene (—CH₂—) moiety could alternatively be another divalent hydrocarbyl moiety; each of R₁-R₄ is the same as or different from one another, with each being independently selected from among hydrogen, C₁-C₆ alkyl and C₆-C₁₀ aryl; each of R₅ and R₆ is the same as or different from the other, with each being independently selected from among hydrogen, C₁-C₆ alkyl; n and m are each selected independently as having a value of from 0 to 4, with the proviso that m and n cannot be 0 at the same time, and x is selected from 1 to 5;

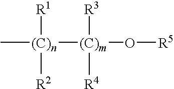

alkoxyalkyls and aryloxyalkyls
wherein each of R₁-R₄ is the same as or different from one another, with each being independently selected from among hydrogen, C₁-C₆ alkyl, and C₆-C₁₀ aryl; R₅ is selected from among hydrogen, C₁-C₆ alkyl, and C₆-C₁₀ aryl; and n and m are selected independently as having a value of from 0 to 4, with the proviso that m and n cannot be 0 at the same time;

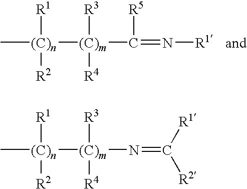

imidoalkyl
   wherein each of R₁, R₂, R₃, R₄, R₅ is the same as or different from one another, with each being independently selected from among hydrogen, C₁-C₆ alkyl, and C₆-C₁₀ aryl; each of R₁′, R₂′ is the same as or different from one another, with each being independently selected from hydrogen, C₁-C₆ alkyl, and C₆-C₁₀ aryl; and n and m are selected independently from 0 to 4, with the proviso that m and n cannot be 0 at the same time;

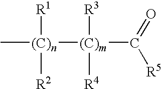

acetylalkyls
   wherein each of R₁-R₄ is the same as or different from one another, with each being independently selected from among hydrogen, C₁-C₆ alkyl, and C₆-C₁₀ aryl; R₅ is selected from among hydrogen, hydroxyl, acetoxy, C₁-C₆ alkyl, C₁-C₁₂ alkylamino, C₆-C₁₀ aryl, and C₁-C₅ alkoxy; and n and m are selected independently from 0 to 4, with the proviso that m and n cannot be 0 at the same time.

One preferred category of precursors in the practice of the present invention includes the following zirconium precursors, identified as “ZR-1” through “ZR-7.”

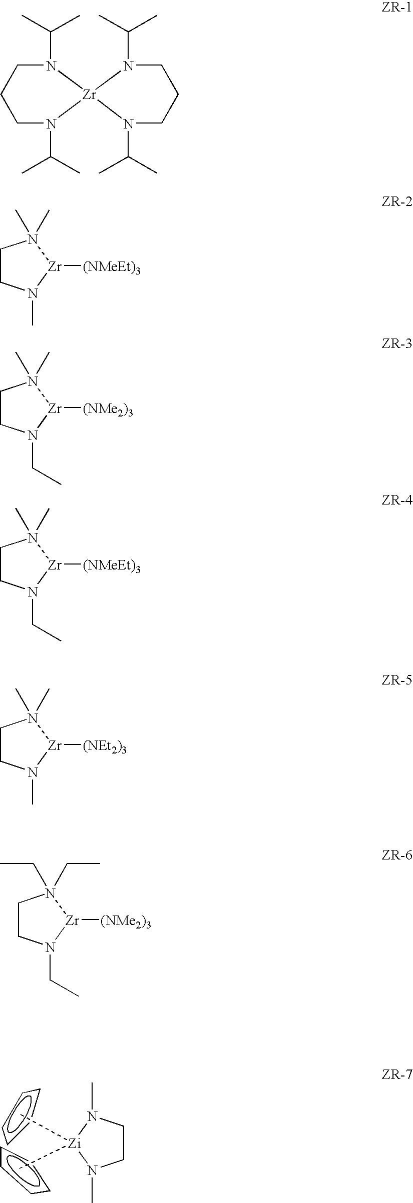

The thermal properties of the foregoing precursors (melting point, m.p. (° C.); T50 (° C.), and residue (%)) are set out in Table II below.

TABLE II

| Category | Precursor | *m.p. (° C.) | T50 (° C.) | Residue (%) |
|---|---|---|---|---|
| Diamides | ZR-1 | liquid | 227 | 2.5 |
| Diamine | ZR-2 | 87 | 213 | 6.1 |
| amides | ZR-3 | 142 | 184 | 5.5 |
| | ZR-4 | 129 | 206 | 5.3 |
| | ZR-5 | 159 | 210 | 8.5 |
| | ZR-6 | Semi-liquid | 207 | 15.7 |
| Cp diamide | ZR-7 | 60 | 234 | 14.0 |

*m.p. was taken from the observed the DSC phase change temperature, not visually confirmed to be the solid-to-liquid transition

Another preferred category of precursors in the practice of the present invention includes the following titanium precursors, identified as “TI-1” through “TI-5.”

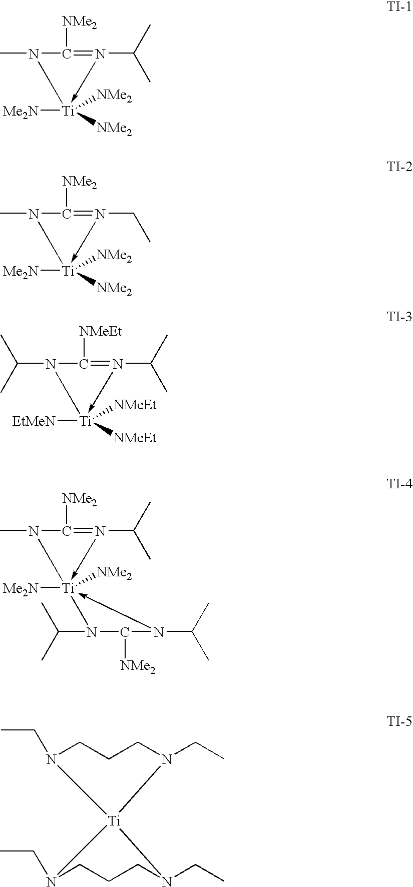

The thermal properties of the foregoing Ti precursors (melting point, m.p. (° C.); T50 (° C.), and residue (%)) are set out in Table III below.

TABLE III

| Category | Precursor | *m.p. (° C.) | T50 (° C.) | Residue (%) |
|---|---|---|---|---|
| Guanidinates | TI-1 | 81 | 185 | 7.7 |
| | TI-2 | liquid | 167 | 3.2 |
| | TI-3 | 48 | 186 | 2.5 |
| | TI-4 | 99 | 200 | 10.6 |
| Di-Amides | TI-5 | Sticky oil | 203 | 6.1 |

*m.p. was taken from the observed the DSC phase change temperature, not visually confirmed to be the solid-to-liquid transition.

Another aspect of the invention relates to Group IV metal complexes having cyclopentadienyl ligands that are useful as CVD and ALD precursors. These precursors address thermal stability issues of homoleptic Group IV amides related to steric congestion and electron deficiency at the metal centers, which impact utility of Group IV amides for CVD/ALD formation of oxide films. Cyclopentadienyl ligands are employed to improve the thermal stability of the corresponding complexes, with acceptable transport properties and process conditions for CVD/ALD applications.

These Group IV metal complexes (wherein M is for example titanium, zirconium, hafnium or the metalloid silicon) have the formula

(C₅R¹R²R³R⁴R⁵)ₙMR₄₋ₙ

wherein each of R¹, R², R³, R⁴ and R⁵ can be the same as or different from the others, and each is independently selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
each R can be the same as or different from the others and each is independently selected from among C₁-C₆ alkyl, C₁-C₆ alkoxy, C₆-C₁₄ aryl, silyl, C₃-C₁₈ alkylsilyl, C₁-C₆ fluoroalkyl, amide, C₁-C₁₂ diamides, C₁-C₁₂ dialkoxides, aminoalkyl, alkoxyalkyl, aryloxyalkyl, imidoalkyl, hydrogen and acetylalkyl;
X is halogen;
n is an integer having a value of from 0 to 4 inclusive; and
A is an alkaloid metal.

The synthesis of such Group IV metal precursors can be carried out in any suitable manner, e.g., by a synthesis such as

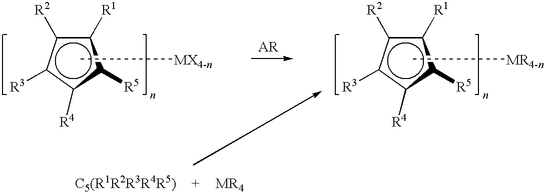

Such reaction can be carried out in diethyl ether or other suitable solvent medium.

As another illustrative example, Cp₂Zr(MeNCH₂CH₂NMe),

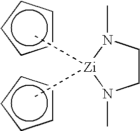

wherein Me is methyl, can be formed by reaction of ZrCp₂Cl₂ with LiMeNCH₂CH₂NMeLi.

A further aspect of the invention relates to Ti guanidinates that are useful as CVD/ALD precursors. These precursors address the issue of carbon contamination of titanium-containing films such as TiN, TiO₂, TiCₓN_{y} and related films, which increases the electrical resistance and decreases the hardness of the deposited titanium-containing film. A root cause of such carbon contamination is the introduction of the carbon impurity from the precursor, e.g., by premature decomposition of the precursor, non-volatile leaving ligands of the precursor, and/or low precursor reactivity with co-reagents.

The titanium guanidinate precursors in such further aspect of the invention have the formula

(R⁵)_{OX-n}Ti[R¹NC(NR²R³)NR⁴]ₙ

wherein:
each of R¹, R², R³, R⁴ and R⁵ can be the same as or different from the others, and each is independently selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
n is an integer having a value of from 0 to 4; and
OX is the oxidation state of the Ti metal center.

A further aspect of the invention relates to titanium diamides having suitability for use as CVD/ALD precursors, of the formulae:

(R¹N(CR²R³)ₘNR⁴)_{OX-n/2}Tiₙ (I)

wherein
each of R¹, R², R³ and R⁴ can be the same as or different from the others, and each is independently selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
m is an integer having a value of from 2 to 6;
n is an integer having a value of from 0 to OX; and
OX is the oxidation state of the Ti metal center, and

(R¹N(CR²)ₘNR⁴)_{OX-n/2}Tiₙ (II)

wherein
each of R¹, R², R³ and R⁴ can be the same as or different from the others, and each is independently selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
m is an integer having a value of from 2 to 6;
n is an integer having a value of from 0 to OX; and
OX is the oxidation state of the Ti metal center.

The above-discussed titanium guanidinates and titanium diamides can be usefully employed as catalysts, e.g., in asymmetric organic transformations and stereoselective polymerizations, and can be readily synthesized by carbodiimide insertion reaction. These precursors can be packaged for storage and delivery with chemical reagent packages of varied types, e.g., the ProE-Vap® package commercially available from ATMI, Inc. (Danbury, Conn., USA).

The aforementioned titanium guanidinates and titanium diamides can be used for forming titanium-containing films in a variety of applications, such as the manufacture of semiconductor devices utilizing titanium-containing barrier layers, the formation of tribological materials, and use in coatings for solar cells, jewelry, optics, etc.

A further aspect of the invention relates to stabilization of metal amides for use in ALD/CVD processes, as precursors for forming metal nitride, metal oxide and metal films as barrier layers or high k dielectrics.

Transition amides, such as Zr(NEtMe)₄, sometimes have problematic thermal stability in specific process applications, leading to premature decomposition during delivery, and resulting adverse effect on the process and associated apparatus, such as line clogging and particulate formation. Metal amides, of the formula M(NR₂)ₒₓ, wherein ox is the oxidation state of the metal M, can undergo ligand dissociation reactions, according to the following reaction:

M(NR₂)ₒₓ→HNR₂+R₂N—NR₂+a dark-colored non-volatile solid material

Experiments with pentakis(dimethylamido)tantalum (PDMAT) have shown that heating of such material at temperature of 90° C. in a sealed stainless steel container for a month produced no decomposition, but that purging of the head space of such a container of PDMAT on a daily basis, to remove volatiles, produced significant decomposition (of up to 30-40%) in a month of heating. This observation has lead to the discovery that metal amide precursors can be stabilized by addition of amines, e.g., by adding dialkylamine to a carrier gas for bubbler delivery of a metal amide precursor. The amines used for such purpose can be of any suitable type, and can for example include amine species such as dimethylamine, ethylmethylamine, diethylamine or higher dialkylamines.

Metal amide precursors susceptible to stabilization in such manner include those of the formulae:

M(NR₂)ₒₓ, wherein ox is the oxidation state of the metal M, wherein the respective R substituents can be the same as or different from one another, and each is independently selected from C₁-C₆ alkyl and C₁-C₁₈ alkylsilyl;
M(NR¹R²)_{ox-2y}(R³N(CR⁴R⁵)_{z}NR⁶)_{y}, wherein R¹, R², R³, R⁴, R⁵ and R⁶ can each be the same as or different from the others, and each is independently selected from C₁-C₆ alkyl and C₁-C₁₈ alkylsilyl, z can be 1 or 2, ox is the oxidation state of the metal M, 2y is equal to or less than ox, wherein M in the respective formulae is selected from among Sc, Y, La, Lu, Ce, Pr, Nd, Pm, Sm, Gd, Tb, Dy, HO, Er, Ti, Hf, Zr, V, Nb, Ta, W, Mo, Al, Ge, Sn, Pb, Se, Te, Bi, and Sb.

The invention therefore achieves stabilization of the precursor during delivery, to prevent clogging and particle generation, by addition of at least one amine to the metal amide precursor prior to or during such delivery to the substrate for deposition thereon of the metal deriving from the metal amide.

Set out below are specific examples of the synthesis and characterization of illustrative precursors of the foregoing type.

### Example 1

### (NMe₂)₃Zr(N(Et)CH₂CH₂NMe₂)

To a 100 ml flask charged with 0.994 gram Zr(NMe₂)₄ (3.72 mmol) and 20 ml Et₂O, 0.43 gram Me₂NCH₂CH₂NEtH (3.72 mmol) was added dropwise at room temperature. The mixture was stirred. After vacuum removal of volatiles, a pale-yellow solid was obtained. The product was characterized as (NMe₂)₃Zr(N(Et)CH₂CH₂NMe₂).

### Example 2

### (NMeEt)₃Zr(N(Me)CH₂CH₂NMe₂)

To a 100 ml flask charged with 1.007 gram Zr(NMeEt)₄ (3.72 mmol) and 20 ml Et₂O, 0.318 gram Me₂NCH₂CH₂NMeH (3.11 mmol) was added dropwise at room temperature. The mixture was stirred. After vacuum removal of volatiles, a pale-yellow solid was obtained. Purification was carried out by sublimation at a 5 gram scale (127 C oil bath, 100 mtorr vacuum). The yield was quantitative. The product was characterized as (NMeEt)₃Zr(N(Me)CH₂CH₂NMe₂).

### Example 3

### (NMe₂)₃Zr(N(Me)CH₂CH₂NMe₂)

To a 100 ml flask charged with 0.979 gram Zr(NMe₂)₄ (3.66 mmol) and 20 ml Et₂O, 0.33 gram Me₂NCH₂CH₂NMeH (3.66 mmol) was added dropwise at room temperature. The mixture was stirred. After vacuum removal of volatiles, pale-yellow solid was obtained. Purification was carried out by sublimation. The product was characterized as (NMe₂)₃Zr(N(Me)CH₂CH₂NMe₂).

### Example 4

### Synthesis of TI-1

The titanium precursor was formed by the following reaction:

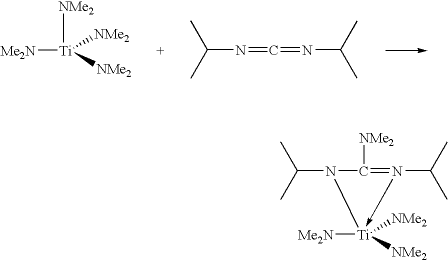

To a 100 ml flask charged with tetrakis(dimethylamino)titanium (5 g, 22.30 mmol) and 50 ml diethyl ether (Et₂O), N,N′-diisopropylcarbodiimide (2.8148 g, 22.30 mmol) was added slowly at room temperature (25° C.). The color of the solution changed from pale yellow to red orange immediately and self-reflux was observed at room temperature. The mixture was stirred at room temperature overnight. Solvent was removed in vacuo and yielded orange-red solid, TI-1 (6.91 grams, 19.72 mmol, 88% yield).

### Example 5

### Synthesis of TI-5

The titanium precursor was formed by the following reaction:

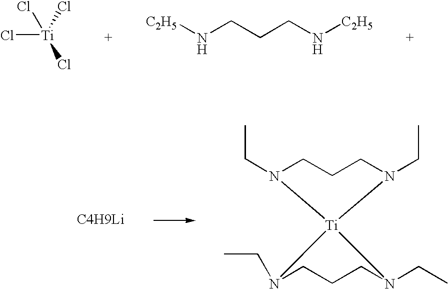

To a 250 ml flask charged with N1,N3-diethylpropane-1,3-diamine (5 g, 38.4 mmol) and 50 ml pentane, 39.5 ml 1.6 M n-butlylithium (63.2 g) was added slowly at 0° C. The mixture turned turbid gradually with white precipitation. The mixture was warmed up to room temperature over a period of 4 hrs. Titanium(IV) chloride (3.6412 g, 19.20 mmol) in 50 ml pentane was added to form N1,N3-diisopropylpropane-1,3-diamide lithium at 0° C. and the mixture turned brown gradually with significant precipitation and white smoke. The mixture was warmed up to room temperature and stirred overnight then filtered to remove LiCl. Pentane was then removed in vacuo to yield a dark brown oily product, TI-5.

### Example 6

### Synthesis of TI-6

The titanium precursor was synthesized by the following reaction:

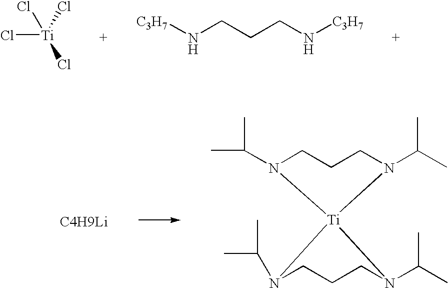

To a 250 ml flask charged with N1,N3-dipropylpropane-1,3-diamine (5 g, 31.6 mmol) and 50 ml Et₂O, 48.13 ml 1.6 M n-butlylithium (63.2) was added slowly at 0° C. The mixture turned turbid gradually with white precipitation. The mixture was warmed up to room temperature over a period of 4 hrs. Titanium(IV) chloride (2.9959 g, 15.79 mmol) in 50 ml pentane was added to form N1,N3-diisopropylpropane-1,3-diamide lithium at 0° C. and the mixture turned brown gradually with significant precipitation and white smoke. The mixture was warmed up to room temperature and stirred overnight. Solvent was removed in vacuo and the residue was dissolved in pentane then filtered to remove LiCl. Pentane was then removed in vacuo to yield a dark brown oily product as the titanium precursor compound.

### Example 7

### Synthesis and Characterization of Cp₂Zr(MeNCH₂CH₂NMe)

To a 250 ml flask charged with 1.956 gram ZrCp₂Cl₂ (6.69 mmol) and 100 ml Et₂O, 0.669 gram LiMeNCH₂CH₂NMeLi (6.69 mmol) was added slowly at 0° C. and the mixture turned orange-red immediately. It was allowed to warm up to room temperature and stirred overnight. After vacuum removal of volatiles and pentane extraction, a brick-red solid at room temperature (25° C.), Cp₂Zr(N(Me)CH₂CH₂N(Me)), was obtained.

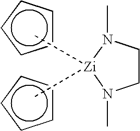

### Calculated: C, 54.67%; H, 6.55%; N, 9.11%.

### Found: C, 54.53%; H, 6.49%; N, 9.03%.

While the invention has been has been described herein in reference to specific aspects, features and illustrative embodiments of the invention, it will be appreciated that the utility of the invention is not thus limited, but rather extends to and encompasses numerous other variations, modifications and alternative embodiments, as will suggest themselves to those of ordinary skill in the field of the present invention, based on the disclosure herein. Correspondingly, the invention as hereinafter claimed is intended to be broadly construed and interpreted, as including all such variations, modifications and alternative embodiments, within its spirit and scope.

1.-37. (canceled)

38. A deposition process, comprising contacting a substrate with a vapor of a precursor to deposit a film thereon containing at least one of zirconium, hafnium, titanium and silicon, wherein said precursor comprises a compound selected from the group consisting of compounds of the formulae:
a) (R¹NC(R³R⁴)ₘNR²)_{(OX-n)/2}MXₙ, wherein R¹, R², R³, R⁴ and X may be the same as or different from one another and each is independently selected from among hydrogen, C₁-C₁₂ alkyl, C₃-C₁₀ cycloalkyl, C₂-C₆ alkenyl, C₁-C₁₂ alkylsilyl, C₆-C₁₀ aryl, —(CH₂)ₓNR′R″, —(CH₂)ₓOR″′ and —NR′R″, wherein x=1, 2 or 3, and R′, R″ and R″′ can be the same as or different from one another, and each is independently selected from H and C₁-C₁₂ alkyl, wherein the subscripts 1 through 12 in the sequence of carbon numbers designates the number of carbon atoms in the alkyl substituent; m is an integer having a value of from 1 to 6, and in addition, X can be selected from among C₁-C₁₂ alkoxy, guanidinates, amidinates and isoureates; and further wherein C(R³R⁴)ₘ can be alkylene; OX is the oxidation state of the metal M; n is an integer having a value of from 0 to OX; m is an integer having a value of from 1 to 6;
b) (R⁶R⁷N)₂M(R⁸NC(R³R⁴)ₘNR⁹) wherein R³, R⁴, R⁶ and R⁷, R⁸ and R⁹ may be the same as or different from one another and each is independently selected from among hydrogen, C₁-C₁₂ alkyl, C₃-C₁₀ cycloalkyl, C₂-C₈ alkenyl, C₁-C₁₂ alkylsilyl, C₆-C₁₀ aryl, —(CH₂)ₓNR′R″, —(CH₂)ₓOR″′ and —NR′R″, wherein x=1, 2 or 3, and R′, R″ and R″′ may be the same as or different from one another, and each is independently selected from H and C₁-C₁₂ alkyl, and further wherein both of R⁶ or R⁷ groups of respective amino nitrogen atoms in the (R⁶R⁷N)₂ moiety can together be alkylene, and C(R³R⁴)ₘ in the (R⁸NC(R³R⁴)ₘNR⁹) moiety can be alkylene; and m is an integer having a value of from 1 to 6; and
c) compounds selected from among (amidinate)_{OX-n}MXₙ, (guanidinate)_{OX-n}MXₙ and (isoureate)_{OX-n}MXₙ, wherein each X can be the same as or different from the others and each is independently selected from among hydrogen, C₁-C₁₂ alkyl, C₃-C₁₀ cycloalkyl, C₂-C₆ alkenyl, C₁-C₁₂ alkylsilyl, C₆-C₁₀ aryl, —(CH₂)ₓNR′R″, —(CH₂)ₓOR″′ and NR′R″, wherein x=1, 2 or 3, and R′, R″ and R″′ can be the same as or different from one another, and each is independently selected from H and C₁-C₁₂ alkyl, wherein the subscripts 1 through 12 in the sequence of carbon numbers designates the number of carbon atoms in the alkyl substituent; m is an integer having a value of from 1 to 6, and in addition, X can be selected from among C₁-C₁₂ alkoxy, guanidinates, amidinates and isoureates; OX is the oxidation state of the metal M; n is an integer having a value of from 0 to OX; m is an integer having a value of from 1 to 6; and M is Ti, Zr, Hf or Si.

39. The process of claim 38, wherein said precursor is contacted with the substrate in the presence of a co-reactant selected from the group consisting of: oxygen, ozone, dinitrogen oxide and water.

40. A deposition process, comprising contacting a substrate with a vapor of a zirconium precursor to deposit a zirconium-containing film thereon, wherein said zirconium precursor comprises a zirconium compound selected from the group consisting of compounds of the formulae:
a) [R¹N(CR³R⁴)ₘNR²]₂Zr wherein R¹, R², R³, and R⁴ may be the same as or different from one another and each is independently selected from among C₁-C₁₂ alkyl;
b) (R⁶R⁷N)₂Zr(R⁸NC(R³R⁴)ₘNR⁹) wherein R³, R⁴, R⁶, R⁷, R⁸ and R⁹ may be the same as or different from one another and each is independently selected from among C₁-C₁₂ alkyl; and
c) (guanidinate)Zr(NR¹⁰R¹¹)₃ wherein guanidinate may be substituted or unsubstituted, R¹⁰ and R¹¹ may be the same as or different from one another and each is independently selected from among C₁-C₁₂ alkyl.

41. A precursor for deposition of at least one of zirconium, hafnium, titanium and silicon, wherein said precursor comprises a compound selected from the group consisting of compounds of the formulae:
a) (R¹NC(R³R⁴)ₘNR2)_{(OX-n)/2}MXₙ, wherein R¹, R², R³, R⁴ and X may be the same as or different from one another and each is independently selected from among hydrogen, C₁-C₁₂ alkyl, C₃-C₁₀ cycloalkyl, C₂-C₆ alkenyl (e.g., vinyl, allyl, etc.), C₁-C₁₂ alkylsilyl (including monoalkylsilyl, dialkylsilyl, and trialkylsilyl), C₆-C₁₀ aryl, —(CH₂)ₓNR′R″, —(CH₂)ₓOR″′ and —NR′R″, wherein x=1, 2 or 3, and R′, R″ and R″′ can be the same as or different from one another, and each is independently selected from H and C₁-C₁₂ alkyl, wherein the subscripts 1 through 12 in the sequence of carbon numbers designates the number of carbon atoms in the alkyl substituent; m is an integer having a value of from 1 to 6, and in addition, X can be selected from among C₁-C₁₂ alkoxy, guanidinates, amidinates and isoureates; OX is the oxidation state of the metal M; n is an integer having a value of from 0 to OX; m is an integer having a value of from 1 to 6; and M is Ti, Zr, H or Si;
b) (R⁶R⁷N)₂M(R⁸NC(R³R⁴)ₘNR⁹) wherein R³, R⁴, R⁶ and R⁷, R⁸ and R⁹ may be the same as or different from one another and each is independently selected from among hydrogen, C₁-C₁₂ alkyl, C₃-C₁₀ cycloalkyl, C₂-C₈ alkenyl, C₁-C₁₂ alkylsilyl, C₆-C₁₀ aryl, —(CH₂)ₓNR′R″, —(CH₂)ₓOR″′ and —NR′R″, wherein x=1, 2 or 3, and R′, R″ and R″′ may be the same as or different from one another, and each is independently selected from H and C₁-C₁₂ alkyl; and m is integer from 1 to 6; and
c) compounds selected from among (amidinate)_{OX-n}MXₙ, (guanidinate)_{OX-n}MXₙ and (isoureate)_{OX-n}MXₙ, wherein each X can be the same as or different from the others and each is independently selected from among hydrogen, C₁-C₁₂ alkyl, C₃-C₁₀ cycloalkyl, C₂-C₆ alkenyl, C₁-C₁₂ alkylsilyl, C₆-C₁₀ aryl, —(CH₂)ₓNR′R″, —(CH₂)ₓOR″′ and NR′R″, wherein x=1, 2 or 3, and R′, R″ and R″′ can be the same as or different from one another, and each is independently selected from H and C₁-C₁₂ alkyl, wherein the subscripts 1 through 12 in the sequence of carbon numbers designates the number of carbon atoms in the alkyl substituent; m is an integer having a value of from 1 to 6, and in addition, X can be selected from among C₁-C₁₂ alkoxy, guanidinates, amidinates and isoureates; OX is the oxidation state of the metal M; n is an integer having a value of from 0 to OX; m is an integer having a value of from 1 to 6; and M is Ti, Zr, H or Si.

42. The precursor of claim 41, in mixture with a co-reactant selected from the group consisting of: oxygen, ozone, dinitrogen oxide and water.

43. A zirconium precursor, selected from the group consisting of compounds of the formulae:
a) [R¹N(CR³R⁴)ₘNR²]₂Zr wherein R¹, R², R³, and R⁴ may be the same as or different from one another and each is independently selected from among C₁-C₁₂ alkyl;
b) (R⁶R⁷N)₂Zr(R⁸NC(R³R⁴)ₘNR⁹) wherein R³, R⁴, R⁶, R⁷, R⁸ and R⁹ may be the same as or different from one another and each is independently selected from among C₁-C₁₂ alkyl; and
c) (guanidinate)Zr(NR¹⁰R¹¹)₃ wherein guanidinate may be substituted or unsubstituted, R¹⁰ and R¹¹ may be the same as or different from one another and each is independently selected from among C₁-C₁₂ alkyl.

44. A precursor formulation, comprising a precursor according to claim 43, and a solvent medium.

45. A liquid delivery process for deposition of a film on a substrate, comprising volatilizing a precursor composition to form a precursor vapor, and contacting said precursor vapor with the substrate to deposit said film thereon, wherein said precursor composition comprises a precursor according to claim 43.

46. A solid delivery process for atomic layer deposition or chemical vapor deposition of a film on a substrate, comprising volatilizing a solid precursor composition to form a precursor vapor, and contacting said precursor vapor with the substrate to deposit said film thereon, wherein said precursor composition comprises a precursor according to claim 43.

47. A metal precursor compound, of the formula
X—M(NR₂)₃
wherein:
M is selected from among Hf, Zr and Ti;
X is selected from among: C₁-C₈ alkyldihydroxy, C₁-C₈ alkyldiamines; and C₁-C₈ alkyloxyamines each R can be the same as or different from others, and is independently selected from among C₁-C₈ alkyl.

48. A method of forming a metal oxide or metal silicate film on a substrate, wherein the metal oxide or metal silicate film is of the formula MO₂ or MSiO₄, respectively, wherein M is a metal selected from among hafnium, zirconium, and titanium, said method comprising contacting said substrate with a precursor vapor composition comprising a precursor of the formula
X—M(NR₂)₃
wherein:
M is selected from among Hf, Zr and Ti;
X is selected from among: C₁-C₈ alkyldioxy, C₁-C₈ alkyldiamines; and C₁-C₈ alkyloxyamines each R can be the same as or different from others, and is independently selected from among C₁-C₈ alkyl.

49. A zirconium precursor, selected from precursors of the formulae:

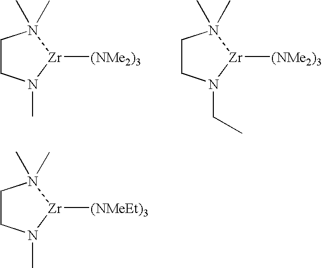

50. A method of forming a zirconium-containing film on a substrate, comprising volatilizing a zirconium precursor compound to form a zirconium precursor vapor, and contacting the zirconium precursor vapor with a substrate to deposit the zirconium-containing film thereon, wherein the zirconium precursor comprises a precursor selected from among (I) and (II):
(I) a precursor comprising a zirconium central atom, and ligands coordinated to the zirconium central, in which each of the ligands coordinated to the zirconium central atom is either an amine or diamine ligand, with at least one of such coordinated ligands being diamine, and wherein each of said amine and diamine ligands is substituted or unsubstituted, and when substituted comprises C₁-C₈ alkyl substituents, each of which may be the same as or different from others in the zirconium precursor; and
(II) precursors selected from among:

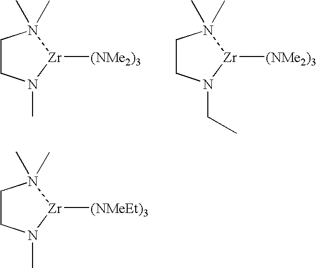

51. A metal precursor selected from among precursors of the formulae (A), (B), (C) and (D):
R³ₙM[N(R¹R⁴)(CR⁵R⁶)ₘN(R²)]_{OX-n} (A)
R³ₙM[E(R¹)(CR⁵R⁶)ₘN(R²)]_{OX-n} (B)
R³ₙM[(R²C═CR⁴)(CR⁵R⁶)ₘN(R¹)]_{OX-n} (C)
R³ₙM[E(CR⁵R⁶)ₘN(R¹R²)]_{OX-n} (D)
wherein:
each of R¹, R², R³, R⁴, R⁵ and R⁶ may be the same as or different from the others, and is independently selected from among H, C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of the metal M;
n is an integer having a value of from 0 to OX;
m is an integer having a value of from 1 to 6;
M is Ti, Zr or Hf; and
E is O or S.

52. A method of forming a zirconium-containing film on a substrate, comprising volatilizing a zirconium precursor compound to form a zirconium precursor vapor, and contacting the zirconium precursor vapor with a substrate to deposit the zirconium-containing film thereon, wherein the zirconium precursor comprises a precursor selected from the group consisting of precursors of the formulae (A), (B), (C) and (D):
R³ₙM[N(R¹R⁴)(CR⁵R⁶)ₘN(R²)]_{OX-n} (A)
R³ₙM[E(R¹)(CR⁵R⁶)ₘN(R²)]_{OX-n} (B)
R³ₙM[(R²C═CR⁴)(CR⁵R⁶)ₘN(R¹)]_{OX-n} (C)
R³ₙM[E(CR⁵R⁶)ₘN(R¹R²)]_{OX-n} (D)
wherein:
each of R', R², R³, R⁴, R⁵ and R⁶ may be the same as or different from the others, and is independently selected from among H, C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, and acetylalkyl;
OX is the oxidation state of the metal M;
n is an integer having a value of from 0 to OX;
m is an integer having a value of from 1 to 6;
M is Ti, Zr or Hf; and
E is O or S.

53. A zirconium precursor, selected from the group consisting of:

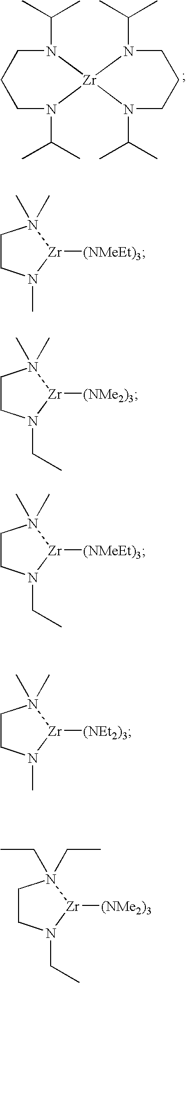

54. A Ti guanidinate of the formula
(R⁵)_{OX-n}Ti[R¹NC(NR²R³)NR⁴]ₙ
wherein:
each of R¹, R², R³, R⁴ and R⁵ can be the same as or different from the others, and each is independently selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
n is an integer having a value of from 0 to 4; and
OX is the oxidation state of the Ti metal center.

55. The process of claim 38, wherein the precursor comprises

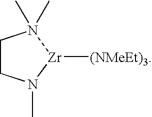

56. The process of claim 38, wherein the precursor comprises [chemical structure]
